(19) United States
(12) Patent Application Publication
(10) Pub. No.: US 2025/0377405 A1
(43) Pub. Date: Dec. 11, 2025

(54) TEST CIRCUIT AND TEST METHOD FOR STACKED CHIP STRUCTURE

(71) Applicant: CXMT Corporation, Hefei City (CN)

(72) Inventor: Jiarui ZHANG, Hefei City (CN)

(73) Assignee: CXMT Corporation, Hefei City (CN)

(21) Appl. No.: 18/969,981

(22) Filed: Dec. 5, 2024

Related U.S. Application Data
(63) Continuation of application No. PCT/CN2024/125706, filed on Oct. 18, 2024.

(30) Foreign Application Priority Data
Jun. 6, 2024 (CN) 202410727842.0

(51) Int. Cl. G01R 31/28

(52) U.S. Cl. CPC G01R 31/2884; G01R 31/2841; G01R 31/2882

(57) ABSTRACT

A test circuit includes: a plurality of conductive paths, a test control circuit, a power control circuit, and a defect detection circuit. The test control circuit is configured to sequentially receive serially input test control signals in response to a test clock signal, and generate and output a plurality of test enable signals in one-to-one correspondence with the plurality of conductive paths; the power control circuit is configured to control, when each of the plurality of test enable signals is in a valid state, a corresponding one of the plurality of conductive paths as a target conductive path to sequentially perform charging and discharging operations; and the defect detection circuit is configured to detect level changes of the plurality of conductive paths separately to generate a plurality of detection identification signals, and generate and output a plurality of detection results in one-to-one correspondence with the plurality of conductive paths.

### CROSS-REFERENCE TO RELATED APPLICATIONS

The present disclosure is a continuation of International Application No. PCT/CN2024/125706 filed on Oct. 18, 2024, which claims priority to Chinese Patent Application No. 202410727842.0 filed on Jun. 6, 2024. The disclosures of the above-referenced applications are hereby incorporated by reference in their entirety.

### BACKGROUND

With the development of integrated circuits, many applications require miniaturization, high speed, high bandwidth, and low power consumption for chips. As Moore's Law gradually reaches its limit, it has become a new trend to improve chip performance and reduce size and power consumption by employing advanced packaging technologies. In 3D stack packaging, a plurality of chips or wafers are stacked, and a plurality of vertical conductive paths are formed to interconnect upper and lower chips, such as through silicon via (TSV) technology, through glass via (TGV) technology, and hybrid bonding technology, so interconnection lines between chips can be shortened to meet demands for high speed, low power consumption, and small area.

However, vertical interconnection in today's stacked chip structure is not yet a fully developed technology; as shown in FIG. 1, faults such as open circuit and short circuit of the conductive path may be caused due to process reasons in the manufacturing process, which may result in an abnormal operation of the stacked chip structure. Therefore, it is necessary to detect faults existing in the conductive path through a test circuit to ensure a normal operation of the stacked chip structure. However, the conventional test circuits and test methods cannot effectively detect all types of defects existing in the conductive path, which may affect the reliability and stability of the stacked chip structure product.

### SUMMARY

The present disclosure relates to the field of semiconductors, and in particular, to a test circuit and a test method for a stacked chip structure.

Embodiments of the present disclosure provide a test circuit and a test method for a stacked chip structure.

The technical solutions of the present disclosure are implemented as follows:

According to a first aspect, an embodiment of the present disclosure provides a test circuit. The test circuit includes: a plurality of conductive paths; a test control circuit configured to sequentially receive serially input test control signals in response to a test clock signal, and generate and output a plurality of test enable signals in one-to-one correspondence with the plurality of conductive paths, where each of the plurality of test enable signals indicates whether a corresponding one of the plurality of conductive paths performs defect detection as a target conductive path in each defect detection; a power control circuit electrically connected to each of the plurality of conductive paths and the test control circuit, separately, and configured to control, when the test enable signal is in a valid state, a corresponding conductive path as the target conductive path to sequentially perform charging and discharging operations; and a defect detection circuit electrically connected to a first end of each of the plurality of conductive paths and the test control circuit, separately, and configured to detect level changes of the plurality of conductive paths separately to generate a plurality of detection identification signals in one-to-one correspondence with the plurality of conductive paths, and generate and output a plurality of detection results in one-to-one correspondence with the plurality of conductive paths based on comparison results between the plurality of detection identification signals and a corresponding plurality of test enable signals.

According to a second aspect, an embodiment of the present disclosure provides a test method for a stacked chip structure. The method includes: sequentially receiving serially input test control signals in response to a test clock signal, and generating and outputting a plurality of test enable signals in one-to-one correspondence with a plurality of conductive paths; controlling, in response to each of the plurality of test enable signals in a valid state, a corresponding one of the plurality of conductive paths as a target conductive path to perform defect detection; detecting level changes of the plurality of conductive paths, separately, during each defect detection to generate a plurality of detection identification signals in one-to-one correspondence with the plurality of conductive paths; generating a plurality of detection results in one-to-one correspondence with the plurality of conductive paths based on comparison results between the plurality of detection identification signals and the corresponding plurality of test enable signals; and latching the plurality of detection results in response to a detection result latch signal after each defect detection is completed.

### BRIEF DESCRIPTION OF THE DRAWINGS

FIG. 1 is a schematic diagram of defect types of a conductive path in a stacked chip structure;

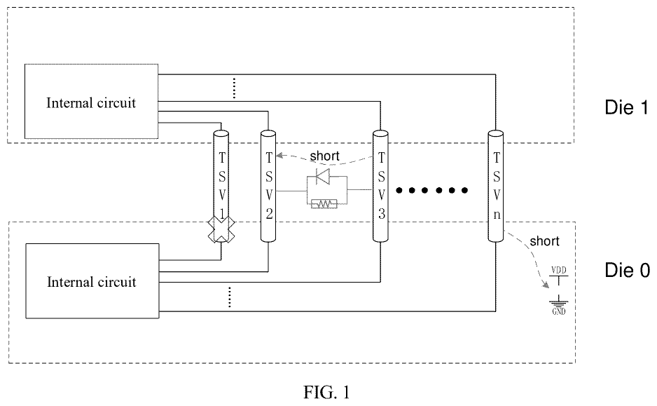

FIG. 2 is a first schematic structural diagram of a test circuit according to an embodiment of the present disclosure;

FIG. 3 is a signal timing diagram corresponding to the test circuit according to the embodiment of the present disclosure (in FIG. 2);

FIG. 4 is a first schematic diagram illustrating a distribution of conductive paths according to an embodiment of the present disclosure;

FIG. 5 is a second schematic diagram illustrating a distribution of conductive paths according to an embodiment of the present disclosure;

FIG. 6 is a second schematic structural diagram of a test circuit according to an embodiment of the present disclosure;

FIG. 7 is a timing diagram of the output of detection result signals in the test circuit according to the embodiment of the present disclosure (in FIG. 6);

FIG. 8 is a third schematic diagram illustrating a distribution of conductive paths according to an embodiment of the present disclosure;

FIG. 9 is a schematic structural diagram of a test control circuit according to an embodiment of the present disclosure;

FIG. 10 is a signal timing diagram corresponding to the test control circuit according to the embodiment of the present disclosure (in FIG. 9);

FIG. 11 is a schematic structural diagram of a defect detection circuit according to an embodiment of the present disclosure;

FIG. 12 is a schematic structural diagram of a defect detection sub-circuit according to an embodiment of the present disclosure;

FIG. 13 is a signal timing diagram corresponding to a defect detection circuit according to an embodiment of the present disclosure;

FIG. 14 is a schematic structural diagram of a power control circuit according to an embodiment of the present disclosure;

FIG. 15 is a schematic structural diagram of a first power control circuit and a second power control circuit according to an embodiment of the present disclosure;

FIG. 16 is a schematic structural diagram of still another first power control circuit and still another second power control circuit according to an embodiment of the present disclosure;

FIG. 17 is a schematic structural diagram of a test region selection circuit according to an embodiment of the present disclosure;

FIG. 18 is a third schematic structural diagram of a test circuit according to an embodiment of the present disclosure;

FIG. 19 is a signal timing diagram corresponding to the test circuit according to the embodiment of the present disclosure (in FIG. 18);

FIG. 20 is a schematic diagram of an operation scenario of a test circuit according to an embodiment of the present disclosure;

FIG. 21 is a schematic diagram of an operation scenario of another test circuit according to an embodiment of the present disclosure;

FIG. 22 is a schematic structural diagram of another test circuit according to an embodiment of the present disclosure;

FIG. 23 is a signal timing diagram corresponding to the test circuit according to the embodiment of the present disclosure (in FIG. 22);

FIG. 24 is a flowchart of a test method for a stacked chip structure according to an embodiment of the present disclosure.

### DETAILED DESCRIPTION

In order to make the objects, technical solutions, and advantages of the present disclosure clearer, the technical solutions of the present disclosure are further elaborated below with reference to the drawings and embodiments. The described embodiments should not be construed as limiting the present disclosure, and all other embodiments obtained by a person of ordinary skill in the art without making creative efforts fall within the protection scope of the present disclosure.

In the following description, reference is made to “some embodiments” which describe subsets of all possible embodiments, but it can be understood that “some embodiments” may be the same subset or different subsets of all possible embodiments, and may be combined with each other without conflict.

The following description will be added if a similar description of “first/second” appears in the application document. Reference is made in the following description to the term “first/second/third” merely to distinguish similar objects and not to imply a particular ordering for the objects. It can be understood that “first/second/third” may be interchanged with a specific order or sequence if permitted, such that the embodiments of the present disclosure described herein can be implemented in an order other than that shown or described herein.

Unless otherwise defined, all technical and scientific terms used herein have the same meaning as commonly understood by those skilled in the art to which the present disclosure belongs. The terms used herein are for the purpose of describing the embodiments of the present disclosure only and are not intended to limit the present disclosure.

Before the embodiments of the present disclosure are described, three directions for describing a three-dimensional structure, which may be used in planes involved in the following embodiments, are defined, and the three directions may include a first direction, a second direction, and a third direction, for example, in a Cartesian coordinate system.

The embodiments of the present disclosure are described in detail below with reference to the drawings.

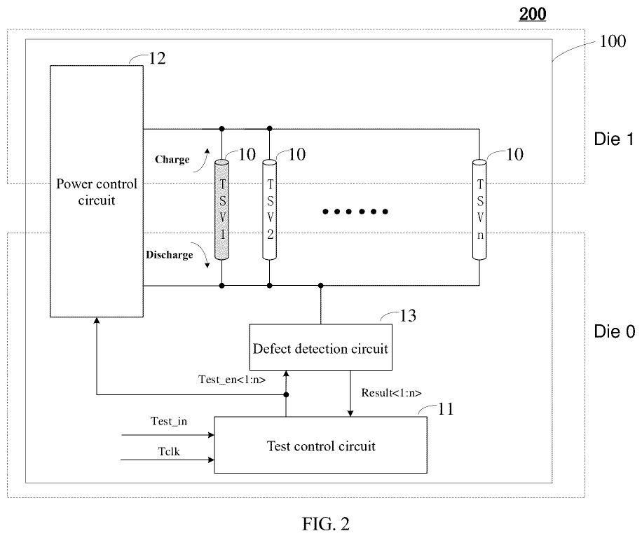

In an embodiment of the present disclosure, a test circuit 100 is provided. Referring to FIG. 2, the test circuit can be applied in a stacked chip structure 200, and the stacked chip structure 200 includes at least a first chip Die0 and a second chip Die1 stacked on the first chip Die0. Specifically, the stacked chip structure 200 may be a stacked semiconductor memory. The test circuit includes:
a plurality of conductive paths 10;
a test control circuit 11 configured to sequentially receive serially input test control signals Test_in in response to a test clock signal Tclk, and generate and output a plurality of test enable signals Test_en<1:n> in one-to-one correspondence with the plurality of conductive paths 10, where each of the plurality of test enable signals Test_en<1:n>indicates whether a corresponding one of the plurality of conductive paths 10 performs defect detection as a target conductive path in each defect detection;
a power control circuit 12 electrically connected to each of the plurality of conductive paths 10 and the test control circuit 11, separately, and configured to control, when the test enable signal Test_en<1:n> is in the valid state, the corresponding conductive path 10 as the target conductive path to sequentially perform charging and discharging operations; and
a defect detection circuit 13 electrically connected to the first end of each of the plurality of conductive paths and the test control circuit 11, separately, and configured to detect level changes of the plurality of conductive paths 10 separately to generate a plurality of detection identification signals in one-to-one correspondence with the plurality of conductive paths, and generate and output a plurality of detection results Result<1:n> in one-to-one correspondence with the plurality of conductive paths 10 based on comparison results between the plurality of detection identification signals and the corresponding plurality of test enable signals.

Exemplarily, the first chip Die0 and the second chip Die1 are electrically connected through the plurality of conductive paths 10 to enable transmission of data signals and control signals.

Exemplarily, the plurality of test enable signals Test_en<1:n> are in one-to-one correspondence with the plurality of conductive paths TSV1-TSVn, where the test enable signals Test_en<1>, Test_en<2>, . . . , and Test_en<n>separately indicate whether the corresponding conductive paths TSV1, TSV2, . . . , and TSVn perform defect detection as the target conductive paths in each defect detection. As shown in FIG. 2, when the test enable signal Test_en<1> is in the valid state, and the other test enable signals Test_en<2:n> are all in the invalid state, in this defect test, only the conductive path TSV1 serves as the target conductive path (gray), and the power control circuit 12 sequentially performs charging and discharging operations on the conductive path TSV1 for defect detection.

It should be noted that in the test circuit and the test method provided in the embodiments of the present disclosure, when all the conductive paths serve as the target conductive paths to complete defect detection (i.e., they are subjected to pull-up charging and then pull-down discharging by the power control circuit), a round of defect test is considered to be completed. Each round of defect test includes a plurality of defect detections, and each defect detection means performing defect detection with one or more different conductive paths as the target conductive paths, i.e., after a charging operation and a discharging operation are performed on the target conductive paths and the defect detection circuit detects the level changes of all the conductive paths to generate and output the detection results, a defect detection is considered to be completed.

It should be further noted that the conductive paths in the embodiments of the present disclosure may be other types of interconnection structures between chips in addition to common through silicon vias (TSVs), for example: connecting wires, through glass vias (TGVs), and hybrid bonding structures, where a copper interconnect technology is a common hybrid bonding technology, which is not limited in the embodiments of the present disclosure. For convenience of illustration, through silicon vias (TSVs) are used as an example of the conductive paths in the embodiments and the drawings of the present disclosure for description.

It should be further noted that in this embodiment, defect detection of all conductive paths can be indicated only by test control signals serially input through one test port, such that test port resources can be effectively saved and test circuit complexity can be effectively reduced. In addition, level changes of all conductive paths are detected to generate detection results of the conductive paths while the defect test is only performed on a target conductive path each time, such that detection of all types of defects can be effectively covered, and the accuracy and comprehensiveness of defect detection of the conductive paths can be improved.

In some embodiments, referring to FIG. 2, the test control circuit is further configured to regenerate and output a plurality of test enable signals Test_en<1:n>after shift-transmitting the test control signals Test_in based on the test clock signal Tclk after each defect detection is completed.

Here, after each defect detection is completed, the test control signals Test_in are shift-transmitted in a walk “1” mode, that is, after the first defect test is completed, the test control signals Test_in are only shifted by 1 bit each time, and then defect detection is performed on a new target conductive path, and so on, until all the conductive paths serve as the target conductive paths to complete the defect detection.

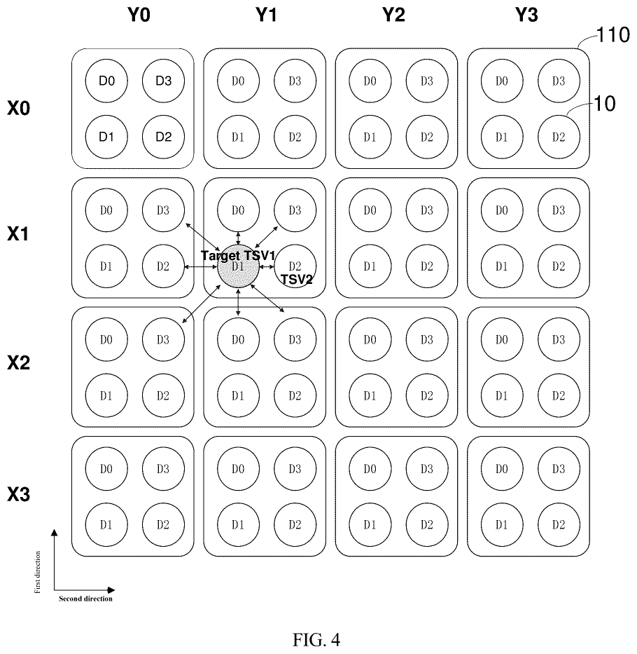

Referring to FIG. 4, the operation principle of the test circuit provided in this embodiment (FIG. 2) is specifically as follows:

At the stage t1-t2, before the first defect test starts, the test control circuit 11 receives the serially input test control signals Test_in based on the test clock signal Tclk.

At the time t2, the test control circuit 11 completes the reception of the test control signals, and generates a plurality of corresponding test enable signals Test_en<1>=1 and Test_en<2:n>=0, where the test enable signal Test_en<1>indicates that the corresponding conductive path TSV1 serves as the target conductive path to perform defect detection. After the time t2, the serially input test control signals are no longer received based on the test clock signal, until the first defect test is completed.

Here, the test clock signal may be blocked or the output of the signal shift-transmission circuit of the test control circuit may be locked after the time t2.

At the stage t2-t3, the power control circuit 12 first performs pull-up charging and then pull-down discharging on the target conductive path TSV1 according to the test enable signal Test_en<1> in the valid state, and the defect detection circuit 13 detects the level changes of all the conductive paths 10 (TSV1-TSVn) separately to generate and output corresponding detection results Result<1:n>.

Specifically, when there is no defect in the target conductive path TSV1, the defect detection circuit 13 may detect the change of the TSV1 from a high level to a low level at the time t3 to generate a detection identification signal flag<1> of “1”, and the test enable signal Test_en<1> in this defect test is in the valid state (indicating that a level change should be detected and the flag<1> of “1” should be output). In this case, a corresponding detection result Result<1> of “0” is output, indicating that the target conductive path TSV1 passes in this defect detection and has no problem. When the target conductive path TSV1 is open or short-circuited to the power supply voltage or the grounding voltage, the TSV1 is constantly at a low level or a high level, and the defect detection circuit 13 cannot detect the change of the TSV1 from the high level to the low level at the time t3, such that a detection identification signal flag<1> of “0” is generated at this time, and the test enable signal Test_en<1> in this defect test is in the valid state (indicating that the flag<1> of “1” should be output). In this case, a corresponding detection result Result<1> of “1” is output, indicating that the target conductive path TSV1 fails in this defect detection and has a defect.

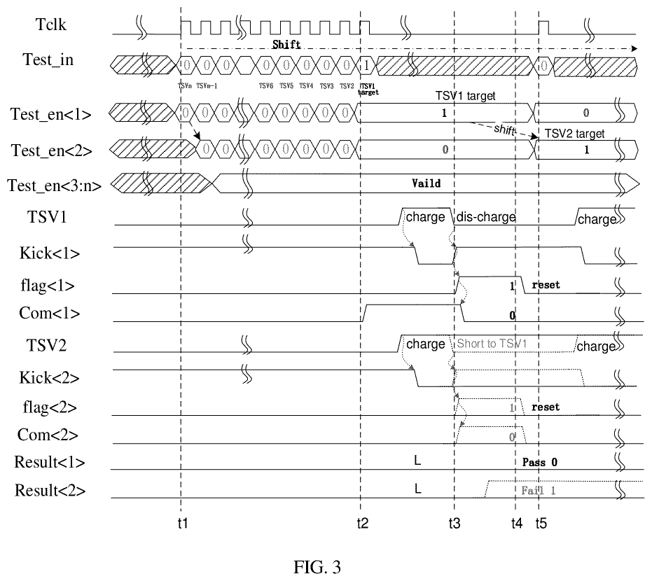

In addition, in this embodiment of the present disclosure, when the TSV1 serves as the target conductive path, the defect detection circuit 13 may further separately detect the level changes of other conductive paths 10 (TSV2-TSVn) simultaneously, in particular, other conductive paths adjacent to the target conductive path TSV1. As shown in FIG. 4, only an adjacent conductive path TSV2 is used as an example herein. As shown by the solid lines in FIG. 3, when only the TSV1 serves as the target conductive path to sequentially perform the charging and discharging operations, if there is no defect of short circuit to the TSV1 in the conductive path TSV2, the defect detection circuit 13 should not detect the change of the TSV2 from a high level to a low level at the time t3 so as to generate a detection identification signal flag<2> of “0”, and the test enable signal Test_en<2> in this defect test is in the invalid state (indicating that no level change should be detected and the flag<2> of “0” should be output). In this case, a corresponding detection result Result<2> of 0 is output, indicating that the conductive path TSV2 passes in this defect detection and has no problem. However, as shown by the dotted lines in FIG. 3, if a short-circuit defect exists between the conductive path TSV2 and the target conductive path TSV1, the defect detection circuit 13 may detect that both the TSV2 and the TSV1 change from a high level to a low level at the time t3, such that a detection identification signal flag<2> of “1” is generated at this time, and the test enable signal Test_en<2> in this defect test is in the invalid state (indicating that the flag<2> of “0” should be output). In this case, a corresponding detection result Result<2> of “1” is output, indicating that the conductive path TSV2 fails in this defect detection and has a defect. In addition, if the short-circuit defect exists between the conductive path TSV2 and the conductive path TSV1, when the conductive path TSV2 serves as the target conductive path for defect detection, a corresponding detection result Result<1> of “1” should be output by the conductive path TSV1, indicating that the conductive path TSV1 fails and has a defect. The defect detection principle of other conductive paths 10 adjacent to the target conductive path is similar, and thus will not be described again.

Therefore, this embodiment of the present disclosure can not only detect a defect of the target conductive path being open or short-circuited to the power supply voltage or the grounding voltage, but also detect a short-circuit defect between the target conductive path and other conductive paths simultaneously.

At the time t4, after the TSV1 serves as the target conductive path to perform the charging and discharging operations, the detection results Result<1:n>corresponding to the conductive paths 10 (TSV1-TSVn) are all generated and output, and the first defect detection is completed.

At the time t5, after the first defect detection is completed, shift-transmission of the test control signals Test_in is continued based on the test clock signal Tclk, and a plurality of test enable signals Test_en<1:n> are regenerated and output. When the test control signals Test in are serial data combinations with only 1 bit as logic “1”, only one of the generated test enable signals is in the valid state to indicate that only one conductive path serves as the target conductive path. In this case, shift-transmission can be performed in a walk “1” mode, that is, the test control signals Test_in are shifted by only 1 bit each time.

Specifically, at the time t2 when the first defect detection is performed, the test enable signal Test_en<1> is generated to be logic “1” and Test_en<2:n> to be logic “0” based on the serially input test control signals Test_in (000 . . . 1); at the time t5, the test control signals Test_in may be shifted by 1 bit based on Tclk, such that data of Test_in is shifted to Test_en<1>, data of Test_en<1> is shifted to Test_en<2>, . . . , and data of Test_en<n−1> is shifted to Test_en<n>. In this case, data “1” is shifted from Test_en<1> to Test_en<2>, and based on a plurality of regenerated test enable signals Test_en<1:n>, the TSV2 serves as the target conductive path to perform the next defect detection, and so on, until all the conductive paths sequentially serve as the target conductive paths to perform the defect detection, such that the defect detection of the current round is completed, and the final detection results Result<1:n>can be output at this time.

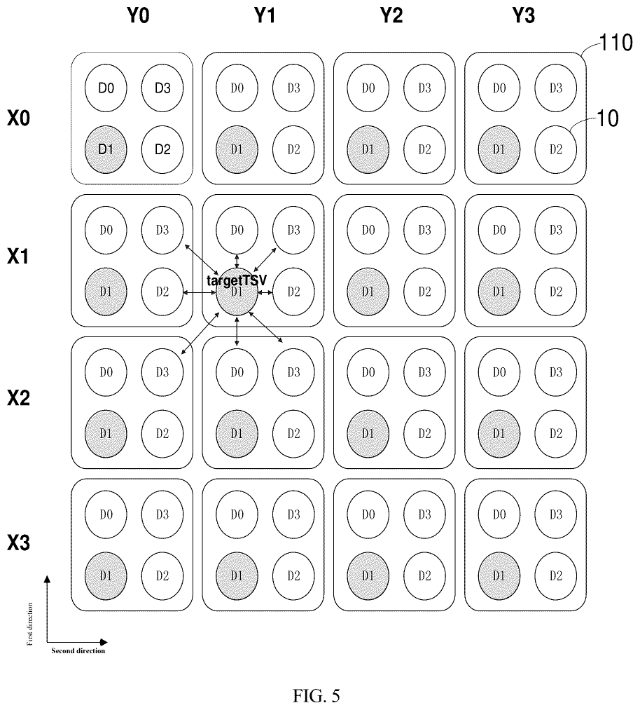

It should be noted that the serially input test control signals Test_in may be any data pattern, may be serial data including only 1 bit as logic “1”, or may be serial data including a plurality of bits as logic “1”. For example, when the test control signals Test_in serially input for the first time are 000 . . . 00011, the generated test enable signals Test_en<1:n> are 000 . . . 00011, and two adjacent conductive paths TSV1 and TSV2 can be designated as the target conductive paths. After the first defect detection is completed, the test control signals Test_in need to be shifted by 2 bits, the test enable signals Test_en<1:n>generated after the shift are 000 . . . 01100, and two adjacent conductive paths TSV3 and TSV4 are designated as the target conductive paths for the next defect detection, and so on, until the defect detection of all the conductive paths is completed. The test data pattern can save half of the test time, but has a defect that a short circuit between two adjacent conductive paths cannot be detected. Still, as shown in FIG. 5, 4n conductive paths to be detected are included. When the test control signals Test_in serially input for the first time are 00010001 . . . 0001, the generated test enable signals Test_en<1:n> are 00010001 . . . 0001, and one of every four conductive paths can be designated as the target conductive path (n conductive paths DO) simultaneously, such that n target conductive paths (n conductive paths DO) can be designated simultaneously in the first defect detection. After the first defect detection is completed, the test control signals Test_in can be shift-transmitted in a walk “1” mode, the test enable signals Test_en<1:n>generated after the shift are 00100010 . . . 0010, and another one of every four conductive paths can be designated as the target conductive path (n conductive paths D1) simultaneously, and so on, such that the defect detection of all the conductive paths can be completed only by three shifts, and the test data pattern can greatly save the time required for the test.

It should be further noted that, in FIG. 4, the test enable signals Test_en<1:n> may also indicate a valid state with a low level (logic “0”), and the detection results Result<1:n>may also indicate that the conductive path 10 has a defect with a low level (logic “0”), and indicate that the conductive path 10 has no defect with a high level (logic “1”), and the above settings of the high level/low level of the signals may be adjusted according to actual designs, which is not specifically limited herein.

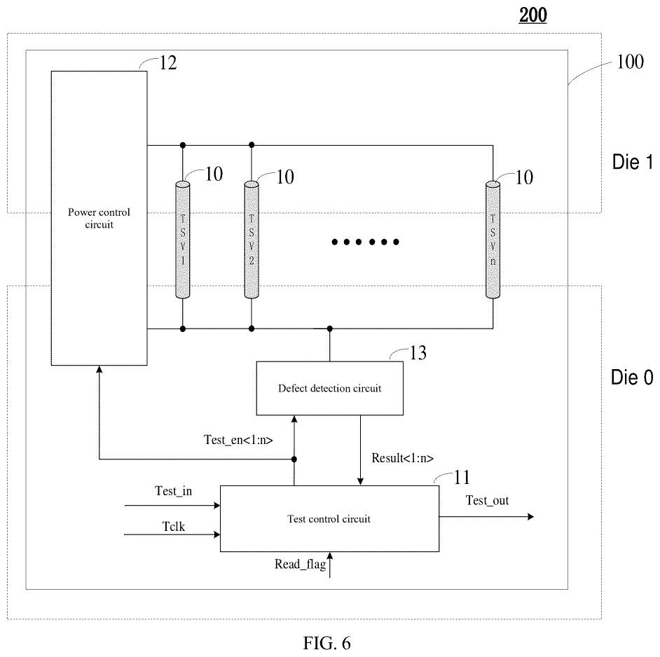

In some embodiments, referring to FIG. 6, the test control circuit 11 is further configured to serially output the detection results Result<1:n>output by the defect detection circuit 13 as test result signals Test_out in sequence based on the test clock signal Tclk after all the conductive paths 10 serve as the target conductive paths to complete defect detection.

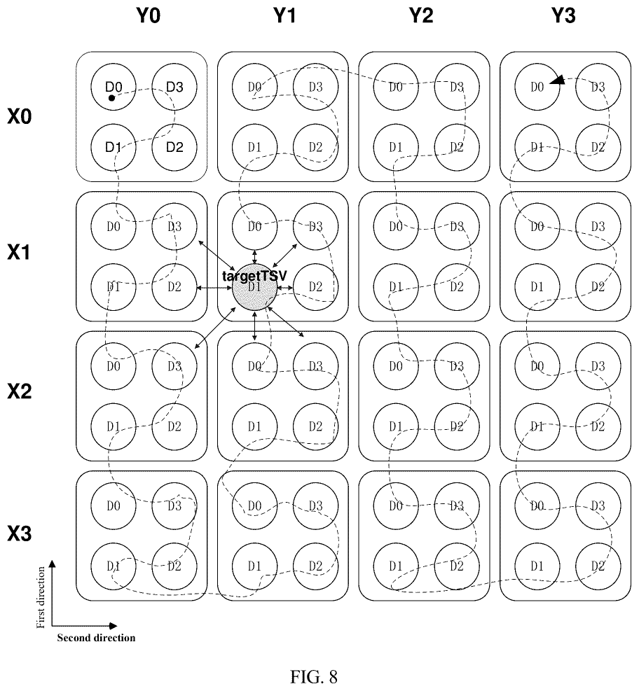

It should be noted that the detection results Result<1:n> of all the conductive paths 10 may be serially output in sequence through one or a few output ports after all the defect detections are completed. When the detection results Result<1:n> are output through a plurality of output ports, the plurality of conductive paths 10 may be divided into a plurality of groups according to their positions, the detection results of the conductive paths 10 in each group may be serially output in sequence through the corresponding output port, and in this case, the test result signals Test_out are multi-bit signals. Since the number of the conductive paths in the stacked chip structure 200 may reach tens of thousands, this embodiment of the present disclosure can avoid the waste of resources due to the occupation of a large number of test ports by the conventional parallel output of the detection results, and can also determine the positions of the conductive paths that have defects according to the serial output sequence of the detection results Result<1:n>. When the detection results Result<1:n> are only serially output through one output port, both the test result signals Test_out and the test control signals Test_in are single-bit signals, and the serial input sequence of the test control signals Test in and the serial output sequence of the detection results Result<1:n>can be the same. As shown in FIG. 8, the transmission sequence can be set according to the adjacent position relationship of the conductive paths 10 so as to reduce wiring on the data transmission path in the test control circuit 11 as much as possible and save the line channel resources in the chip. In addition, the output of the detection results Result<1:n>can reuse the receiving circuit and the transmission path of the test control signals Test_in in this case, such that the complexity of the test control circuit can be reduced, and the chip area occupied by the test control circuit can be effectively reduced.

In some embodiments, with continued reference to FIG. 6, the test control circuit 11 is further configured to receive a result readout identification signal Read_flag, read the detection results Result<1:n>output by the defect detection circuit 13 based on the test clock signal Tclk when the result readout identification signal Read_flag indicates that the test control circuit 11 is in a test result readout phase, and serially output the read detection results Result<1:n> as the test result signals Test_out in sequence based on the test clock signal Tclk when the result readout identification signal Read_flag indicates that the test control circuit 11 is in a data transmission phase.

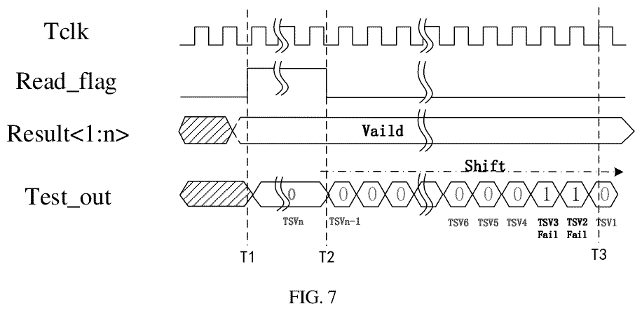

With reference to FIG. 7, the test circuit provided in this embodiment (FIG. 6) will be described with respect to the output operation of the detection results.

Before the time T1, after all the conductive paths 10 serve as the target conductive paths to complete defect detection, the current round of defect test has been completed, and the final detection results Result<1:n>corresponding to all the conductive paths 10 have been generated and output by the defect detection circuit 13. At this time, the result readout identification signal Read_flag is at a low level, indicating that the test control circuit 11 is in the data transmission phase (the data transmitted at this time is the test control signals Test_in to control the conductive paths to perform the defect test), and the test control circuit 11 does not perform an operation on the detection results Result<1:n>.

At the stage T1-T2, the result readout identification signal Read_flag is turned from the low level to a high level to indicate that the test control circuit 11 is in the test result readout phase. At this time, the test control circuit 11 reads all the detection results Result<1:n> to the output end of the internal transmission circuit based on the test clock signal Tclk, so as to wait for the test control circuit to output the detection results in sequence.

At the stage T2-T3, the result readout identification signal Read_flag is again turned from the high level to the low level to indicate that the test control circuit 11 is in the data transmission phase. At this time, the test control circuit 11 serially outputs the detection results Result<1:n> that have been read to the output end of the internal transmission circuit as the test result signals Test_out in sequence based on the test clock signal Tclk. Since the conductive path TSV1 is closest to the input port and the conductive path TSVn is closest to the output port, the detection result that is first output based on the test clock signal Tclk is Result<n>, . . . , and the detection result that is last output is Result<1>, where the (n-1)^{th} and (n-2)^{th} output detection results Result<2> and Result<3> are “1”, indicating that the corresponding conductive paths TSV2 and TSV3 have defects.

It should be noted that in FIG. 7, the high level/low level of the result readout identification signal Read_flag may be interchanged, that is, the result readout identification signal Read_flag may indicate that the test control circuit 11 is in the test result readout phase when it is at the high level, and indicate that the test control circuit 11 is in the data transmission phase when the result readout identification signal Read_flag is at the low level, which is not specifically limited herein.

In some embodiments, the test control circuit 10 is further configured to reset the test enable signals Test_en<1:n> in response to a first reset signal Rst1 after all the detection results Result<1:n> are output.

It should be noted that after all the detection results Result<1:n> are serially output, the current round of defect detection has been completed and the results have been recorded, and then all the control signals, including the test enable signals, in the test circuit 100 should be reset, so as to prevent an abnormal test due to the relevant control signals not being reset when the next round of defect test or other tests are performed.

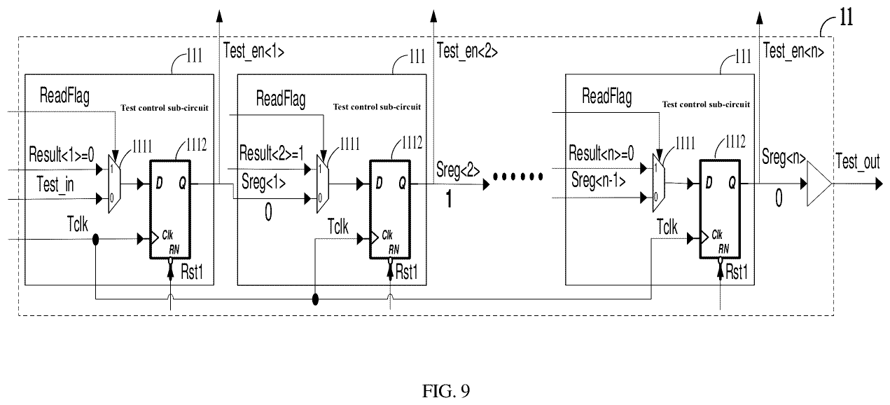

In some embodiments, referring to FIG. 9, the test control circuit 11 includes a plurality of test control sub-circuits 111 cascaded and the plurality of test control sub-circuits 111 are in one-to-one correspondence with the plurality of conductive paths 10.

The first input end of the test control sub-circuit 111 of the first stage receives the test control signals Test_in, the output end of the test control sub-circuit 111 of each stage is electrically connected to the first input end of the test control sub-circuit 111 of next stage, the second input end of the test control sub-circuit 111 of each stage receives a corresponding detection result Result<1:n>, the clock end of the test control sub-circuit 111 of each stage receives the test clock signal Tclk, the control end of the test control sub-circuit 111 of each stage receives the result readout identification signal Read_flag, the reset end of the test control sub-circuit 1111 of each stage receives the first reset signal Rst1, the output end of the test control sub-circuit 111 of each stage outputs a corresponding test enable signal Test_en<i> (i is a positive integer less than or equal to n) or a corresponding detection result Result<i>, and the output end of the test control sub-circuit 111 of the last stage is further configured to serially output the detection results Result<i> as the test result signals Test_out in sequence.

In some embodiments, referring to FIG. 9, each test control sub-circuit 111 includes:
a selector 1111, where the first input end of the selector 1111 serves as the first input end of the test control sub-circuit 111, the second input end of the selector 1111 serves as the second input end of the test control sub-circuit to receive the corresponding detection result Result<i>, and the control end of the selector 1111 serves as the control end of the test control sub-circuit 111 to receive the readout identification signal Read_flag; and
a first D flip-flop 1112, where the input end of the first D flip-flop 1112 is electrically connected to the output end of the selector 1111, the clock end of the first D flip-flop 1112 serves as the control end of the test control sub-circuit 111 to receive the test clock signal Tclk, the output end of the first D flip-flop 1112 serves as the output end of the test control sub-circuit 111 to output the test enable signals Test_en<i>, and the reset end of the first D flip-flop receives the first reset signal Rst1.

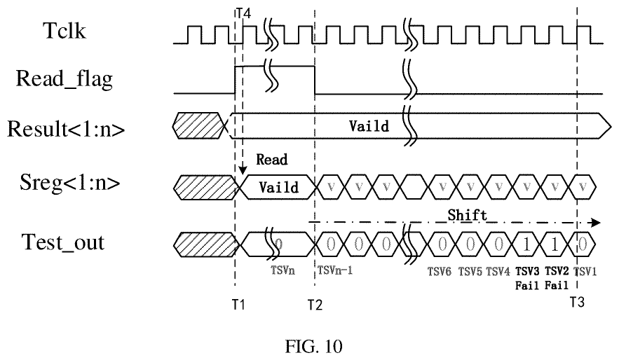

It should be noted that in the embodiments of the present disclosure, the input of the test control signals Test_in and the output of the detection results Result<1:n>share a set of transmission circuits. Referring to FIG. 10, before the time T1, the readout identification signal Read_flag always indicates that the test control circuit 11 is in the data transmission phase, the selector 1111 outputs the test control signals Test_in to the input end of the first D flip-flop 1112 based on the readout identification signal Read_flag in the low level state (logic “0”), and the selector 1111 has not read the detection result Result<i>generated in the current round of defect test. At this time, the data transmitted/shifted by the test control circuit 11 serves as the test control signals Test_in to generate the corresponding test enable signals Test_en<1:n>, and the data Sreg<1:n>output by the test control sub-circuit of each stage based on the test clock signal Tclk serves as the corresponding test enable signals Test_en<1:n> (with Sreg<1> as the test enable signal Test_en<1>, Sreg<2> as the test enable signal Test_en<2>, . . . , and Sreg<n> as the test enable signal Test_en<n>). At the stage T1-T2, when the readout identification signal Read_flag indicates that the test control circuit 11 is in the detection result readout phase, the test control sub-circuit 111 of each stage reads the corresponding detection results Result<1:n> to the output end (the test control sub-circuit of the first stage reads the detection result Result<1> to the output end thereof, the test control sub-circuit of the second stage reads the detection result Result<2> to the output end thereof . . . and the test control sub-circuit of the last stage reads the detection result Result<n> to the output end thereof). Specifically, the selector 1111 outputs the detection result Result<i> to the input end of the first D flip-flop 1112 based on the readout identification signal Read_flag in the high level state (logic “1”), the first D flip-flop 1112 reads the detection result Result<i> to the output end thereof based on the first rising edge (time T4) of the test clock signal Tclk after the time T1, and outputs the result as Sreg<i>. In addition, at the stage T1-T2, since the selector 1111 clock-selects the detection result Result<i> as the output, at this stage, the test control sub-circuit of each stage performs the operation of reading the detection result Result<i> and does not perform the shift-transmission operation of data. At the stage T2-T3, the Read_flag indicates that the test control circuit 11 is in the data transmission phase again, and since the detection results Result<1:n> of the current round of defect test have been read to the output end of the test control sub-circuit 111 of each stage, at this time, the data shift-transmitted in the test control circuit 11 is the detection results Result<1:n>. After the corresponding detection result Result<n>output is output by the test control sub-circuit of the last stage, based on the test clock signal Tclk, the plurality of cascaded test control sub-circuits sequentially shift other detection results Result<n−1>, . . . , and Result<1> to the output end of the test control sub-circuit of the last stage. At this time, the data Sreg<n>output by the test control sub-circuit of the last stage is output as the test result signals Test_out.

In other embodiments, a set of transmission circuits may be separately provided for the transmission of the test control signals Test_in and the transmission of the detection results Result<1:n>. Although the circuit area and the power consumption may be increased, in this solution, the transmission of the test control signals and the transmission of the detection results may be performed synchronously without interfering with each other, which may effectively improve the test efficiency and further ensure the accuracy of the test results.

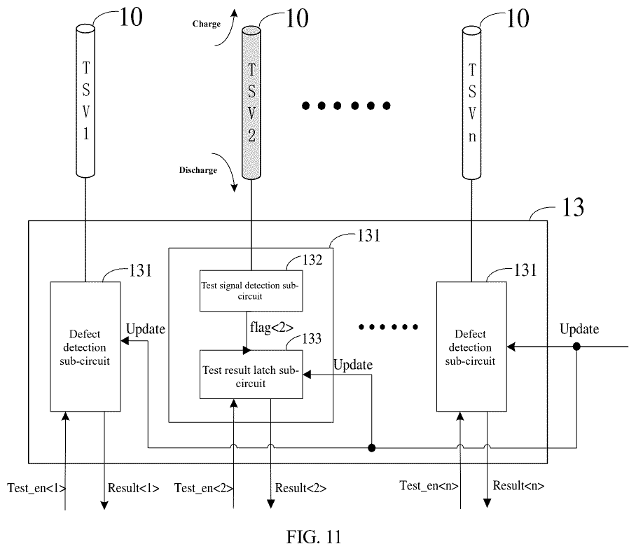

In some embodiments, referring to FIG. 11, the defect detection circuit 13 is further configured to receive a detection result latch signal Update and latch each of the detection results Result<1:n> in response to the detection result latch signal Update after each defect detection is completed.

Here, after the charging and discharging operations are sequentially performed on the target conductive path (TSV2), the defect detection circuit 13 performs level detection on all the conductive paths 10 separately to generate a plurality of detection identification signals flag<1:n>. Each detection identification signal flag<i> is compared with the corresponding test enable signal Test_en<i> to generate a comparison result Com<i>. After the comparison result Com<i> is generated (i.e., after each defect detection is completed), the defect detection circuit 13 outputs and latches the comparison result Com<i> as the detection result Result<i> in time based on the detection result latch signal Update, so as to record the detection result of each conductive path 10 in each defect detection in time to prevent the loss of detection data.

In some embodiments, with continued reference to FIG. 11, the defect detection circuit 13 is further configured to latch, based on the current comparison result Com<i>between each detection identification signal flag<i> and a corresponding test enable signal Test_en<i>, each detection result Result<i> that is kept or updated in response to the received detection result latch signal Update after any of the conductive paths 10 serves as the target conductive path to perform the charging and discharging operations sequentially.

When the detection identification signal flag<i> is different from the corresponding test enable signal Test_en<i>, the corresponding detection result Result<i> is kept or updated to be a first level, and when the detection identification signal flag<i> is the same as the corresponding test enable signal Test_en<i>, the corresponding detection result Result<i> is kept unchanged; and the detection result Result<i>being the first level indicates that the corresponding conductive path 10 has a defect, and the detection result Result<i>being a second level indicates that the corresponding conductive path 10 has no defect, where the first level is opposite to the second level.

Here, when the detection result latch signal Update is the first level, the detection result Result<i> is kept or updated based on the current comparison result Com<i>, and when the detection result latch signal Update is the second level, the detection result Result<i> is locked, and in this case, the comparison result Com<i>has no impact on the detection result Result<i>, where the first level may be a high level or a low level, and the second level is correspondingly a low level or a high level.

It should be noted that as described above, each round of defect test includes a plurality of defect detections, and only one conductive path 10 serves as the target conductive path for each defect detection. If there are n conductive paths 10 to be detected, n defect detections are required for each round of defect test, and in the embodiments of the present disclosure, the defect detection circuit 13 in each defect detection detects level changes of all the conductive paths 10 to generate the detection results Result<1:n>. When n defect detections are performed, the detection results Result<1:n>corresponding to the conductive paths 10 are also generated for n times, and the detection results Result<1:n>generated each time are likely to be different. As shown in FIG. 4, if there is an open-circuit defect in the conductive path D1 at the X1/Y1 position, the defect can be detected only in the defect detection with the conductive path as the target conductive path, and the detection result corresponding to the conductive path D1 at the X1/Y1 position should be “1” (fail), while in other defect detections, the detection results corresponding to the conductive path D1 at the X1/Y1 position should be “0” (pass). If the conductive path D1 at the X1/Y1 position has a defect of being short-circuited to the conductive path D2 at the X1/Y1 position, the defect can be detected only in the defect detection with the conductive path D2 at the X1/Y1 position as the target conductive path. Therefore, it is necessary to consider which defect detection shall prevail for the detection results Result<1:n> and how to update or keep the detection results Result<1:n>after each defect detection.

In the embodiments of the present disclosure, the detection results Result<1:n> of each conductive path are updated or kept in a stick “1” mode, which is specifically shown in Table 1 below. That is, when the comparison result Com<i>corresponding to an i^{th} conductive path 10 in any defect detection is “1” (the detection identification signal flag<i> is different from the test enable signal Test_en<i>, and i is a positive integer greater than or equal to 1 and less than or equal to n), it is indicated that the i^{th} conductive path has a defect, its detection result Result<i> is updated to “1”, and the detection result is kept until the current round of detection is completed to output the detection result Result<i> of “1”. When the comparison result Com<i>corresponding to the i^{th} conductive path 10 is “0” (the detection identification signal flag<i> and the test enable signal Test_en<i> are the same), it is indicated that the i^{th} conductive path has no defect, and the original detection result Result<i> is kept unchanged.

TABLE 1

| Current | Current | Current | Previous | | Current |
|---|---|---|---|---|---|
| detection | detection | detection | detection | | detection |
| flag<i> | Test_en<i> | Com<i> | Result<i> | Update | Result<i> |
| 0 | 0 | 0 | Pass“0” | Keep/ | Pass“0” |
| | | | | update | |
| 0 | 1 | 1 | Pass“0” | Update | Fail“1” |
| 1 | 0 | 1 | Fail“1” | Keep | Fail“1” |
| 1 | 1 | 0 | Fail“1” | Keep | Fail“1” |

In other embodiments, the detection results Result<1:n> of each conductive path may be updated or kept in the stick “0” mode, which is not limited in the embodiments of the present disclosure.

In some embodiments, with continued reference to FIG. 11, the defect detection circuit 13 includes a plurality of defect detection sub-circuits 131, and the plurality of defect detection sub-circuits 131 are in one-to-one correspondence with the plurality of conductive paths 10.

Each defect detection sub-circuit 131 includes:
a test signal detection sub-circuit 132 electrically connected to the first end of a corresponding conductive path 10 and configured to detect the level change of the conductive path to generate and output the detection identification signal flag<i>; and
a test result latch sub-circuit 133 electrically connected to the test signal detection sub-circuit 132 and the test control circuit 11 and configured to generate the detection result Result<i> based on the comparison result between the detection identification signal flag<i> and the corresponding test enable signal Test_en<i>, and latch the detection result Result<i>in response to the detection result latch signal Update.

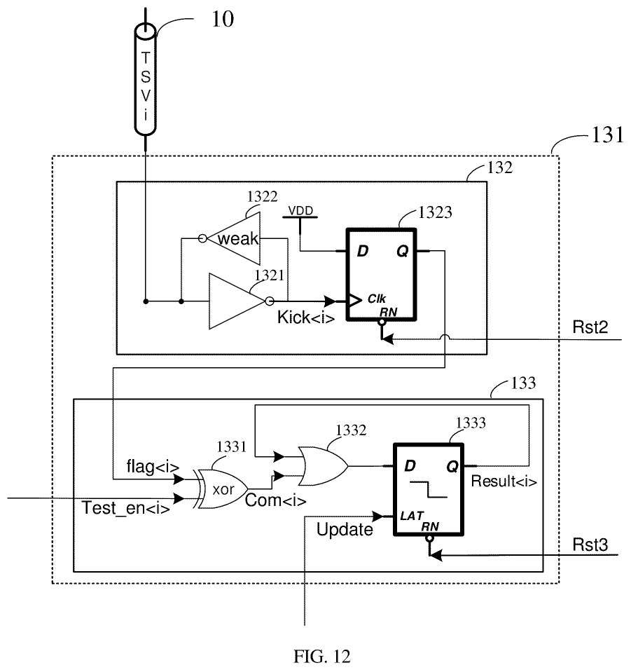

In some embodiments, referring to FIG. 12, the test signal detection sub-circuit 132 includes:
a first NOT gate 1321, where the input end of the first NOT gate 1321 is electrically connected to the first end of the corresponding conductive path 10;
a second NOT gate 1322, where the input end of the second NOT gate 1322 is electrically connected to the output end of the first NOT gate 1321, and the output end of the second NOT gate 1322 is electrically connected to the input end of the first NOT gate 1321; and
a second D flip-flop 1323, where the input end of the second D flip-flop 1323 is electrically connected to a power supply voltage VDD, the clock end of the second D flip-flop 1323 is electrically connected to the output end of the first NOT gate 1321, and the output end of the second D flip-flop 1323 outputs the detection identification signal flag<i>.

The test result latch sub-circuit 133 includes:
a first exclusive-OR gate 1331, where the first input end of the first exclusive-OR gate 1331 is electrically connected to the output end of the second D flip-flop 1323, and the second input end of the first exclusive-OR gate 1331 receives the corresponding test enable signal Test_en<i>;
a first OR gate 1332, where the first input end of the first OR gate 1332 is electrically connected to the output end of the first exclusive-OR gate 1331; and
a latch 1333, where the input end of the latch 1333 is electrically connected to the output end of the first OR gate 1332, the control end of the latch 1333 receives the detection result latch signal Update, the output end of the latch 1333 outputs the detection result Result<i>, and the output end of the latch 1333 is further electrically connected to the second input end of the first OR gate 1332.

In some embodiments, with continued reference to FIG. 12, the reset end of the second D flip-flop 1323 receives a second reset signal Rst2, and the second D flip-flop 1323 resets the detection identification signal flag<i> in response to the second reset signal Rst2 after each latching of the detection result Result<i>; and the reset end of the latch 1333 receives a third reset signal Rst3, and the latch 1333 resets the detection result Result<i> in response to the third reset signal Rst3 after all the detection results Result<1:n> are output.

It should be noted that in each defect detection, the level change state of the conductive path 10 needs to be detected again to generate a new detection identification signal flag<i>. In order to avoid the current detection identification signal flag<i> from affecting the detection identification signal flag<i>generated in the next defect detection, the detection result Result<i>needs to be reset after being latched based on the detection result latch signal Update. Meanwhile, in order to avoid the influence of the current round of defect test on the next round of defect test or other tests, the latch 1333 needs to reset the output after all the detection results Result<1:n> are serially output.

It should be noted that the first reset signal Rst1 and the third reset signal Rst3 may be the same signal since they both instruct the output of relevant circuits to be reset after all the detection results Result<1:n> are serially output.

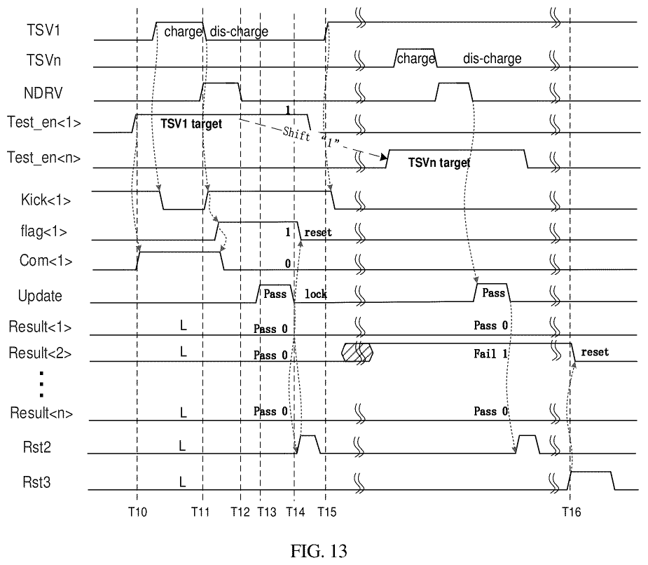

With reference to FIG. 13, the operation principle of the defect detection circuit 13 provided in this embodiment (FIG. 11 to FIG. 12) is explained (here, only one conductive path 10 is set as the target conductive path for each defect detection, for example).

Starting from the time T10, the first defect detection of the current round of defect test is started based on the test enable signals Test_en<1:n> (Test_en<1>=logic “1”, and Test_en<2:n>=logic “0”) output by the test control circuit, and the power control circuit 12 first performs charging and discharging on the conductive path TSV1 in sequence.

At the time T11, the test signal detection sub-circuit 132 detects the level change of the conductive path TSV1. If the conductive path TSV1 has no defect, the conductive path TSV1 is changed from charging to discharging, and the first end of the conductive path TSV1 is changed from a high level to a low level. At this time, a trigger signal Kick<1>output by the first NOT gate 1321 in the test signal detection sub-circuit 132, which is electrically connected to the first end of the conductive path TSV1, is changed from a low level to a high level, and the second D flip-flop 1323 sets the output detection identification signal flag<1> to a high level (logic “1”) according to the power supply voltage VDD connected to the input end based on the change of the trigger signal Kick<1>received by the clock end. The test result latch sub-circuit 133 compares the detection identification signal flag<1>with the test enable signal Test_en<1> to generate and output the detection result Result<1>. Specifically, the first exclusive-OR gate 1311 performs an exclusive-OR operation on the detection identification signal flag<1> (logic “1”) with the test enable signal Test_en<1> (logic “1”) and then outputs the comparison result Com<1> of a low level (logic “0”), and the first OR gate 1332 outputs the low-level signal (logic “0”) to the input end of the latch 1333 based on the comparison result Com<1> (logic “0”) and the current detection result Result<1> (reset to logic “0” by the third reset signal Rst3 before the start of the defect test).

Since the test enable signals Test_en<2:n> of other conductive paths TSV2-TSVn are at a low level (logic “0”), the power control circuit 12 does not sequentially perform the complete operations of charging and discharging on the conductive paths. If none of the conductive paths TSV2-TSVn has a defect, the corresponding trigger signals Kick<2:n>should generate a rising edge, the detection identification signals flag<2:n>should also be kept at a low level (reset to logic “0” by the second reset signal Rst2 after each defect detection), and the corresponding comparison result Com<2:n> and the corresponding first OR gate 1332 are also output at a low level (logic “0”).

At the time T13, since the power control circuit 12 has completed the discharging operation on the conductive path TSV1 at the previous time T12, the test signal detection sub-circuit 132 and the test result latch sub-circuit 133 should have completed the level detection operations on all the conductive paths at this time. In this case, the detection result latch signal Update is changed from a low level to a high level, and the latch 1333 is switched from a latch state to a pass-through state, i.e., the low-level signal (logic “0”) output from the first OR gate 1332 is output as the detection result Result<i>, i.e., the detection result continues to be kept at a low level (logic “0”) to indicate that the conductive paths TSV1-TSVn have no defect (pass).

At the time T14, the detection result latch signal Update is changed from the high level to the low level, the latch 1333 is switched from the pass-through state to the latch state, and the detection result Result<i>output by the current defect detection is locked.

Since the output of the latch 1333 is connected to the second input end of the first OR gate 1332, if any conductive path TSVi has a defect and the output of the locked detection result Result<i> is a high level (logic “1”), the output of the corresponding first OR gate 1332 is set to a high level (logic “1”), and then the comparison results Com<i> of other defect tests will no longer affect the output of the first OR gate 1332 and the detection result Result<i>, and the detection result Result<i>will be always kept at the high level (logic “1”), so as to achieve the purpose of stick “1” of the detection result. After the detection result Result<i> is locked, the detection identification signal flag<i> may be reset based on the second reset signal Rst2 to avoid affecting the results of other subsequent defect detections.

It should be noted that the latch 1333 may be in the latch state when the detection result latch signal Update is at the high level, and in the pass-through state when the detection result latch signal Update is at the low level, which is not limited in the embodiments of the present disclosure.

At the time T15, the test control circuit 13 controls the test enable signals Test_en<1:n> for shift-transmission, the logic “1” is shifted from the test enable signal Test_en<1> to the test enable signal Test_en<2>, and the power control circuit 12 starts the second defect detection by sequentially performing charging and discharging with the next conductive path TSV2 as the target conductive path, and so on, until all the conductive paths TSV1-TSVn serve as the target conductive paths to complete the defect detection so as to generate the final detection results Result<1:n>.

It should be noted that in each defect detection, all the conductive paths may be charged while only the target conductive path may be discharged; or, only the target conductive path may be charged while all the conductive paths may be discharged; or, only the target conductive path may undergo both charging and discharging operations, while other conductive paths may undergo neither charging nor discharging operations, which is not limited in the embodiments of the present disclosure.

At the time T16, after the test control circuit has serially output all the final detection results Result<1:n> based on the result readout identification signal Read_flag, the latch 1333 may be reset based on the third reset signal Rst3.

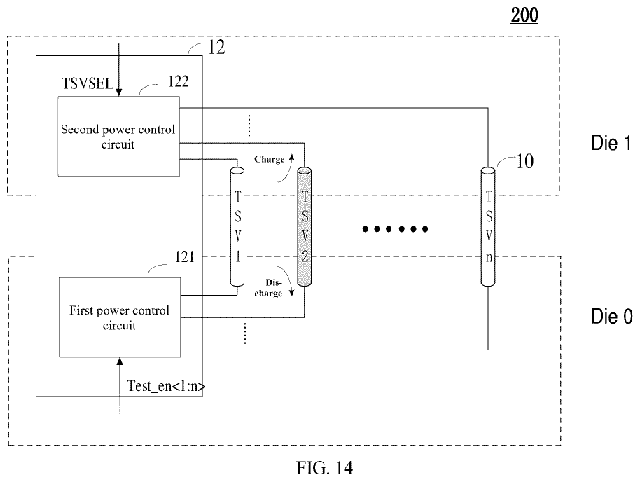

In some embodiments, referring to FIG. 14, the power control circuit 12 includes:
a first power control circuit 121 electrically connected to the first end of each conductive path 10 and the test control circuit 11, separately, and configured to control the first end of the target conductive path to be electrically connected to the power supply voltage VDD or a grounding voltage GND when the test enable signal Test_en<1:n> is in the valid state; and
a second power control circuit 122 electrically connected to the second end of each conductive path 10, separately, and configured to control the second end of the conductive path 10 to be electrically connected to the grounding voltage GND or the power supply voltage VDD.

In some embodiments, referring to FIG. 4, FIG. 5, and FIG. 8, the plurality of conductive paths 10 are divided into a plurality of conductive path groups 110 arranged in arrays, each conductive path group 110 includes 1×m conductive paths 10 arranged in an array, and 1 and m are both positive integers greater than or equal to 2.

It should be noted that 1 and m may be the same positive integer or different positive integers. In FIG. 4, FIG. 5, and FIG. 8, 1=m=2 is used as an example for illustration. Specifically, the values of 1 and m may be adjusted according to the number, position, and arrangement of the conductive paths, which is not limited in the embodiments of the present disclosure.

In some embodiments, referring to FIG. 5 and FIG. 14, the first power control circuit 121 is further configured to use one conductive path (D1) in each conductive path group 110 as the target conductive path based on the plurality of test enable signals Test_en<1:n> in each defect detection, and control the first end of each target conductive path to be electrically connected to the power supply voltage VDD or the grounding voltage GND.

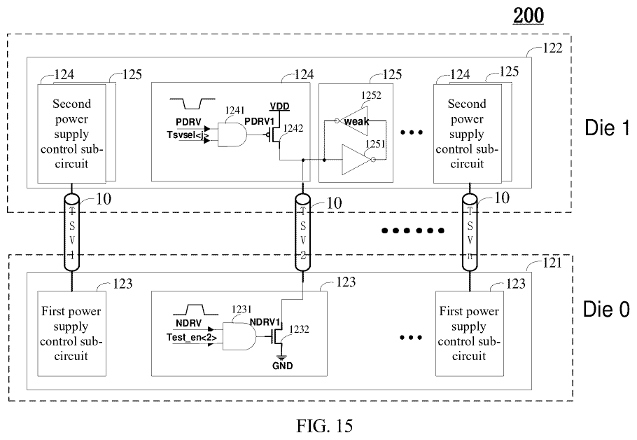

In some embodiments, referring to FIG. 4, FIG. 14, and FIG. 15, the second power control circuit 122 is further configured to receive a test region selection signal TSVSEL (using p position regions as an example, where p is a positive integer), and control the second end of a selected conductive path (the conductive path D1 at the X1/Y1 position) to be electrically connected to the grounding voltage or the power supply voltage based on the test region selection signal TSVSEL.

The test region selection signal TSVSEL includes a plurality of test region selection sub-signals Tsvsel<1: p> in one-to-one correspondence with the plurality of position regions (using p position regions as an example, where p is a positive integer), each test region selection sub-signal Tsvsel<j> (j is a positive integer less than or equal to p) indicates whether conductive paths in the corresponding position region are selected; and each position region includes at least one conductive path group 110.

Here, in each defect detection, the second power control circuit 122 may select all the conductive paths of a single position region or some of the position regions for discharging/charging based on the test region selection signal TSVSEL, so as to reduce the transient current and power consumption of the test circuit 100. When the test circuit 100 has a strong tolerance to the transient current and the power consumption, in each defect detection, the second power control circuit 122 may also select all the position regions based on the test region selection signal TSVSEL for discharging/charging all the conductive paths simultaneously, so as to simplify the control operation of the test circuit 100, which is not limited in the embodiments of the present disclosure.

It should be noted that each position region may only include one conductive path group 110. As shown in FIG. 4, where 16 position regions are used as an example for illustration, each position region includes a conductive path group 110 in a position combination, the conductive path group 110 at the X0/Y0 position corresponds to the first position region, and the conductive path group 110 at the X0/Y1 position corresponds to the second position region. When the first position region is selected based on the test region selection signal TSVSEL, only the conductive paths in the conductive path group 110 at the X0/Y0 position all need to be charged or discharged, resulting in small transient current and power consumption in the test circuit, but the 16 test region selection sub-signals Tsvsel<j> and the control circuit need to separately select among 16 conductive path groups 110, which occupies more circuit area and transmission channels. Alternatively, each position region may include a plurality of conductive path groups 110. With continued reference to FIG. 4, where four position regions are used as an example for illustration, each position region includes conductive paths 110 in four position combinations. The four conductive path groups 110 at the positions X0/Y0, X0/Y1, X0/Y2, and X0/Y3 correspond to the first position region (of course, X0/Y0, X0/Y1, X1/Y0, and X1/Y1 may also be grouped into the first position region without limitation), and the four conductive path groups 110 at the positions X1/Y0, X1/Y1, X1/Y2, and X1/Y3 correspond to the second position region. When the first position region is selected based on the test region selection signal TSVSEL, all the conductive paths at the positions X0/Y0, X0/Y1, X0/Y2, and X0/Y3 need to be charged or discharged simultaneously, resulting in a large transient current and power consumption in the test circuit, but only four test region selection sub-signals Tsvsel<j> and the control circuit are needed to select among 16 conductive path groups 110, which occupies less circuit area and transmission line channels. Specifically, adjustments can be made based on circuit design factors such as transient current, transient power consumption, occupied area, and occupied line channels, which is not limited in the embodiments of the present disclosure.

In some embodiments, the first power control circuit 121 may also select some of the conductive paths in a single position region or some of the position regions as the target conductive paths for the charging/discharging operation based on both the test region selection signal TSVSEL and the test enable signal Test_en.

In some embodiments, referring to FIG. 15, the first power control circuit 121 includes a plurality of first power supply control sub-circuits 123, the second power control circuit 122 includes a plurality of second power supply control sub-circuits 124, and the plurality of first power supply control sub-circuits 123 and the plurality of second power supply control sub-circuits 124 are in one-to-one correspondence with the plurality of conductive paths 10, separately.

In some embodiments, the first power supply control sub-circuit 123 is used for controlling discharging of the conductive path 10, and the second power supply control sub-circuit 124 is used for controlling charging of the conductive path 10. With continued reference to FIG. 15, the first power supply control sub-circuit 123 includes:
a first AND gate 1231, where the first input end of the first AND gate 1231 receives a pull-down control signal NDRV, and the second input end of the first AND gate 1231 receives the corresponding test enable signal Test_en<i>; and
a first N-type transistor 1232, where the first end of the first N-type transistor 1232 is electrically connected to the first end of the conductive path 10, the second end of the first N-type transistor 1232 is electrically connected to the grounding voltage GND, and the control end of the first N-type transistor 1232 is electrically connected to the output end of the first AND gate 1231.

The second power supply control sub-circuit 124 includes:
a second AND gate 1241, where the first input end of the second AND gate 1241 receives a pull-up control signal PDRV, and the second input end of the second AND gate 1241 receives the corresponding test region selection sub-signal Tsvsel<j>; and
a first P-type transistor 1242, where the first end of the first P-type transistor 1242 is electrically connected to the second end of the conductive path 10, the second end of the first P-type transistor 1242 is electrically connected to the power supply voltage VDD, and the control end of the first P-type transistor 1242 is electrically connected to the output end of the second AND gate 1241.

It should be noted that in the embodiments of the present disclosure, the first power supply control sub-circuit 123 is used for controlling discharging of the conductive path 10, and the second power supply control sub-circuit 124 is used for controlling charging of the conductive path 10.

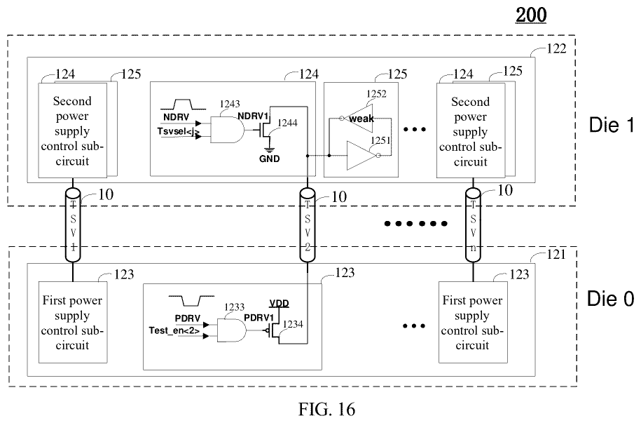

In some embodiments, the first power supply control sub-circuit 123 is used for controlling charging of the conductive path 10, and the second power supply control sub-circuit 124 is used for controlling discharging of the conductive path 10. With reference to FIG. 16, the first power supply control sub-circuit 123 includes:
a third AND gate 1233, where the first input end of the third AND gate 1233 receives a pull-up control signal PDRV, and the second input end of the third AND gate 1233 receives the corresponding test enable signal Test_en<i>; and
a second P-type transistor 1234, where the first end of the second P-type transistor 1234 is electrically connected to the first end of the conductive path 10, the second end of the second P-type transistor 1234 is electrically connected to the power supply voltage VDD, and the control end of the second P-type transistor 1234 is electrically connected to the output end of the third AND gate 1233.

The second power supply control sub-circuit 124 includes:
a fourth AND gate 1243, where the first input end of the fourth AND gate 1243 receives a pull-down control signal NDRV, and the second input end of the fourth AND gate 1243 receives a corresponding test region selection sub-signal Tsvsel<j>; and
a second N-type transistor 1244, where the first end of the second N-type transistor 1244 is electrically connected to the second end of the conductive path 10, the second end of the second N-type transistor 1244 is electrically connected to the grounding voltage, and the control end of the second N-type transistor 1244 is electrically connected to the output end of the fourth AND gate 1243.

In some embodiments, with continued reference to FIG. 15 and FIG. 16, the second power control circuit 122 further includes a plurality of holding circuits 125, and the plurality of holding circuits 125 are in one-to-one correspondence with the plurality of conductive paths 10.

The holding circuit 125 includes:
a third NOT gate 1251, where the input end of the third NOT gate 1251 is electrically connected to the second end of a corresponding conductive path 10; and
a fourth NOT gate 1252, where the input end of the fourth NOT gate 1252 is electrically connected to the output end of the third NOT gate 1251, and the output end of the fourth NOT gate 1252 is electrically connected to the input end of the third NOT gate 1251.

It should be noted that in other embodiments, the holding circuit 125 may also be disposed in the first power control circuit 121, and the holding circuit 125 may also be disposed in the first power control circuit 121 and the second power control circuit 122, separately, which is not limited in the present disclosure.

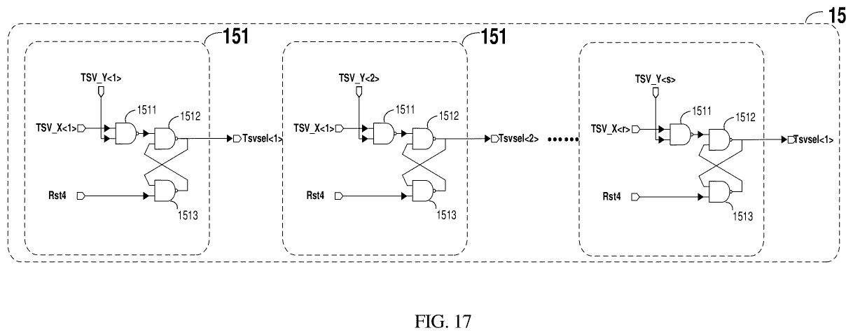

In some embodiments, as shown in FIG. 17, the test circuit 100 further includes: a test region selection circuit 15, and the test region selection circuit 15 includes a plurality of test region selection sub-circuits 151 in one-to-one correspondence with the plurality of position regions. Each test region selection sub-circuit 151 includes:
a first NAND gate 1511, where the first input end of the first NAND gate 1511 receives first position selection sub-signals TSV_X<1:r>, and the second input end of the first NAND gate 1511 receives second position selection sub-signals TSV_Y<1:s>;
a second NAND gate 1512, where the first input end of the second NAND gate 1512 is connected to the output end of the first NAND gate 1511, and the output end of the second NAND gate 1512 outputs test region selection sub-signals Tsvsel<1:j>; and
a third NAND gate 1513, where the first input end of the third NAND gate 1513 is connected to the output end of the second NAND gate 1512, the second input end of the third NAND gate 1513 receives a fourth reset signal Rst4, and the output end of the third NAND gate 1513 is connected to the second input end of the second NAND gate 1512.

Here, s and r are both positive integers, and s×r-j.

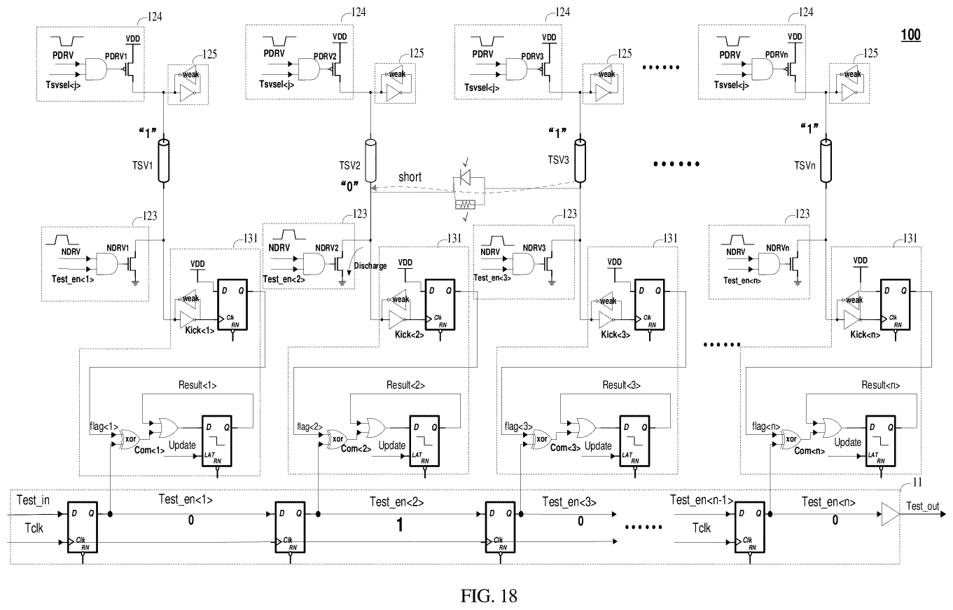

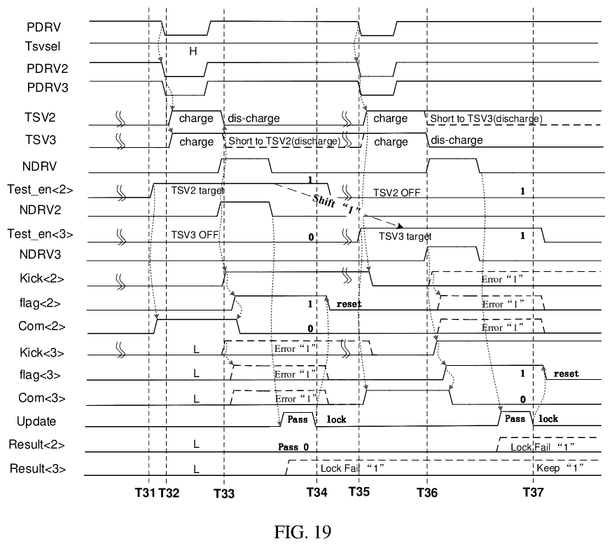

FIG. 18 shows a test circuit 100 according to an embodiment of the present disclosure, where the structure (not shown in the figure) in which the input of the test control signals Test_in and the output of the detection results Result<1:n> in the test control circuit 11 share a set of transmission circuits can refer to FIG. 6, FIG. 7, FIG. 9, and FIG. 10 and the description of the foregoing embodiments. With reference to FIG. 19, the operation principle of the test circuit 100 according to the embodiment of the present disclosure (FIG. 18) is described (here, the test control signals Test_in are serial data combinations with only 1 bit as logic “1”, the first power supply control sub-circuit 123 is used for controlling discharging of the conductive path 10, and the second power supply control sub-circuit 124 is used for controlling charging of the conductive path 10, for example).

Before the time T31, the test control circuit 11 serially inputs the test control signals Test in based on the test clock signal Tclk, and completes the first defect detection with the conductive path TSV1 as the target conductive path based on the test enable signals Test_en<1>=1 and Test_en<2:n>=0 (not shown in the figure, and the operation principle of this stage can refer to FIG. 4 and the detailed description of the foregoing embodiments).

At the time T31, after the first defect detection is completed, the test control circuit 11 shift-transmits the test control signals Test_in by 1 bit (shift “1”) based on the test clock signal Tclk, and regenerates and outputs a plurality of test enable signals Test_en<1:n>. At this time, only the test enable signal Test_en<2> is logic “1”, the remaining test enable signals are all logic “0”, and the conductive path TSV2 serves as the target conductive path.

At the time T32, the second power supply control sub-circuit 124 simultaneously charges all the conductive paths TSV2-TSV3 of the selected position region (assuming that the conductive paths TSV2 and TSV3 belong to the same position region) based on the pull-up control signal PDRV and the test region selection sub-signal Tsvsel<j>.

At the time T33, the first power supply control sub-circuit 123 only performs a pull-down discharging operation on the conductive path TSV2 based on the pull-down control signal NDRV and the test enable signals Test_en<1:n> (where only the test enable signal Test_en<2> is logic “1”), and the defect detection sub-circuit 131 will detect the change of the conductive path TSV2 from a high level to a low level to generate a detection identification signal flag<2> of a high level (logic “1”). Since the Test_en<2> (which can be understood as the expected level change detection result) and the detection identification signal flag<2> (which can be understood as the actual level change detection result) are the same, the output comparison result Com<2> is at a low level (logic “0”).

As shown by the solid lines in the figure, the discharging operation of the conductive path TSV3 is not performed in normal conditions, and the corresponding defect detection sub-circuit 131 will not detect the change of the conductive path TSV3 from the high level to the low level. The generated detection identification signal flag<3> (which can be understood as the actual level change detection result) and the Test_en<3> (which can be understood as the expected level change detection result) are both the same logic “0”, and the output comparison result Com<3> is also at the low level (logic “0”).

As shown by the dotted lines in the figure, if there is a short-circuit defect between the conductive paths TSV2 and TSV3, at the time T33, the conductive path TSV3 will perform the discharging operation in synchronization with the conductive path TSV2, and the corresponding defect detection sub-circuit 131 will detect the change of the conductive path TSV3 from the high level to the low level. In this case, the generated detection identification signal flag<3> (which can be understood as the actual level change detection result) is logic “1”, which is different from logic “0” of the Test_en<3> (which can be understood as the expected level change detection result), such that the output comparison result Com<3> is changed to the high level (logic “1”).

At the time T34, as shown by the dotted lines in the figure, the defect detection sub-circuit 131 will lock the high level of the comparison result Com<3> of the high level (logic “1”) as the detection result Result<3> based on the detection result latch signal Update, and the Result<3> of the high level (logic “1”) indicates that there is a defect in the conductive path TSV3.

At the time T35, the test control circuit 11 continues to shift-transmit the test control signals Test_in by 1 bit based on the test clock signal Tclk. At this time, only the test enable signal Test_en<3> is logic “1”, the remaining test enable signals are all logic “0”, and the conductive path TSV3 serves as the target conductive path.

Thereafter, the second power supply control sub-circuit 124 simultaneously charges all the conductive paths TSV2-TSV3 of the selected position region based on the pull-up control signal PDRV and the test region selection sub-signal Tsvsel<j>.

At the time T36, the first power supply control sub-circuit 123 only performs the pull-down discharging operation on the conductive path TSV3 based on the pull-down control signal NDRV and the test enable signals Test_en<1:n> (only the test enable signal Test_en<3>is logic “1” at this time), similarly to the aforementioned defect detection with the conductive path TSV2 as the target conductive path. As shown by the dotted lines in the figure, when there is a short-circuit defect between the conductive paths TSV2 and TSV3, the conductive path TSV2 will perform the discharging operation in synchronization with the conductive path TSV3 at the time T36, and the defect detection sub-circuit 131 can detect the change from the high level to the low level in both the conductive path TSV2 and the conductive path TSV3. In this case, the generated detection identification signal flag<2> (which can be understood as the actual level change detection result) is logic “1”, which is different from logic “0” of the Test_en<2> (which can be understood as the expected level change detection result), such that the output comparison result Com<2> is changed to the high level (logic “1”).

At the time T37, as shown by the dotted lines in the figure, the defect detection sub-circuit 131 will lock the high level of the comparison result Com<2> of the high level (logic “1”) as the detection result Result<2> based on the detection result latch signal Update, and the Result<2> of the high level (logic “1”) indicates that there is a defect in the conductive path TSV2.

By analogy, all the conductive paths serve as the target conductive paths to complete defect detection, and then all the final detection results Result<1:n> are serially output as the detection result signals Test_out based on the result readout identification signal Read_flag. For content of this part, reference may be made to FIG. 9, FIG. 10, and the description of the foregoing embodiments.

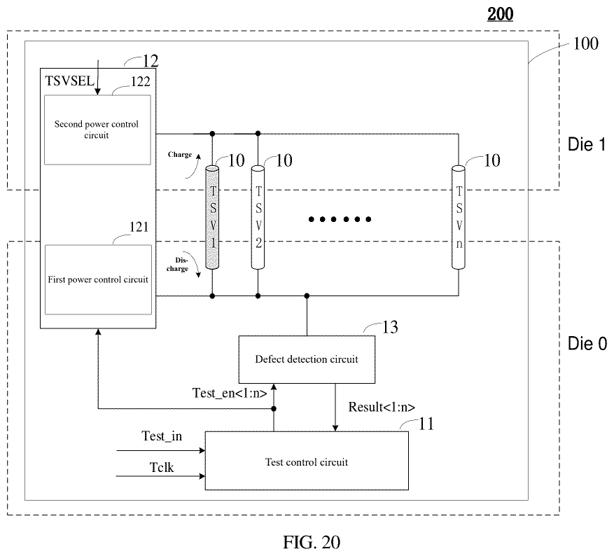

In some embodiments, referring to FIG. 20, the test circuit is applied in a stacked chip structure 200, and the stacked chip structure 200 includes: a first chip Die0 and a second chip Die1 stacked on the first chip Die0.

The first power control circuit 121, the test control circuit 11, and the defect detection circuit 13 are all arranged in the first chip Die0, the second power control circuit 122 is arranged in the second chip Die1, and the conductive paths 10 are used for transmitting signals between the first chip Die0 and the second chip Die1.

It should be noted that the stacked chip structure 200 may be a wafer on wafer (WoW) memory chip, the first memory chip Die0 is a control circuit chip, the second memory chip Die1 is a memory array chip, and the first chip and the second chip are stacked in the third direction that is perpendicular to the top surfaces of the chips.

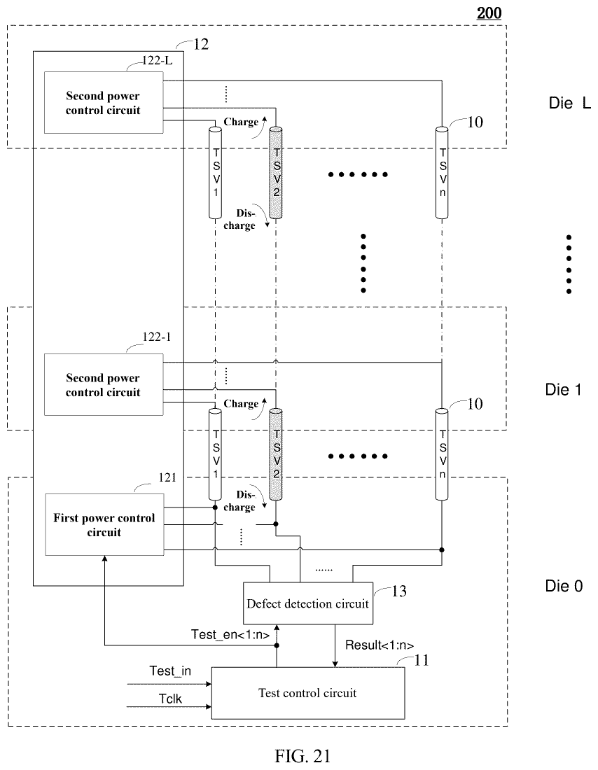

In some embodiments, referring to FIG. 21, the test circuit is applied in a stacked chip structure 200, and the stacked chip structure 200 includes: a first chip Die0 and at least one second chip Die1-DieL stacked on the first chip Die0.

The first power control circuit 121, the test control circuit 11, and the defect detection circuit 13 are all arranged in the first chip Die0, a plurality of second power control circuits 122-1, . . . , and 122-L are separately arranged in the plurality of second chips Die1-DieL, and the conductive paths 10 are used for transmitting signals between the first chip Die0 and the second chips Die1-DieL and transmitting signals between the second chips Die1-DieL.

It should be noted that the stacked chip structure 200 may also be an HBM, the stacked chip structure 200 may include a plurality of second memory chips, and the first chip and the plurality of second chips are stacked in the third direction that is perpendicular to the top surfaces of the chips. The first memory chip Die0 is a logic chip, the second memory chips Die1-DieL are all memory chips, and L may be Apr. 8, 2012/16, . . . , which is not limited in the embodiments of the present disclosure.

It should be noted that in the embodiments of the present disclosure, the pull-up control signal PDRV or the pull-down control signal NDRV received by the second power supply control sub-circuit 124 may be transmitted from the first chip Die0 to the second chip Die1, so as to ensure that the control signal received by the second power supply control sub-circuit 124 in the second chip Die1 is consistent with the control signals received by other circuits in the first chip Die0 in terms of the timing sequence, and prevent an inaccurate defect detection result due to the inconsistent timing sequence of the control signals of different chips in the test circuit.

It should be noted that in the embodiments of the present disclosure, the test region selection circuit 15 may be disposed in the first chip Die0; or in the second chip Die1, in which case the first position selection sub-signal TSV_X<1:r> and the second position selection sub-signal TSV_Y<1:s>received by the test region selection sub-circuit 151 may be transmitted from the first chip Die0 to the second chip Die1.

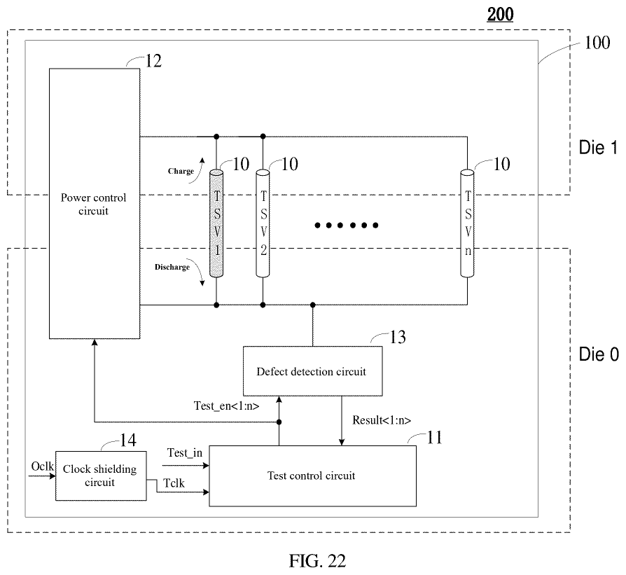

In some embodiments, referring to FIG. 22, the test circuit 100 further includes:
a clock shielding circuit 14 connected to the test control circuit 11 and configured to receive an initial clock signal Oclk, generate and output the test clock signal Tclk based on the initial clock signal Oclk when none of the conductive paths 10 performs defect detection, and output no test clock signal Tclk when any of the conductive paths 10 performs defect detection.

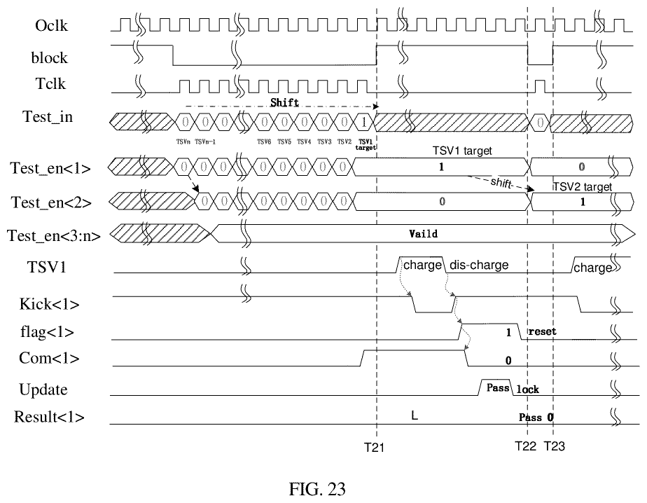

It should be noted that as shown in FIG. 23, none of the conductive paths 10 performing defect detection includes the following three cases: before the current round of defect test (before the time T21, the current round of defect test has not started, and the test control signals Test_in need to be input based on the test clock signal Tclk); during the interval between two defect detections (at the stage T22-T23, the first defect detection with the TSV1 as the target conductive path is completed at the time T22, the second defect detection with the TSV2 as the target conductive path is started at the time T23, and the test clock signal Tclk is required to shift-transmit the test enable signals Test_en<1:n>between T22 and T23); and after the defect detection of all the conductive paths, where the test clock signal Tclk is required to serially output the detection results Result<1:n> as the detection result signals Test_out (not shown in the figure). As shown in FIG. 23, it is not necessary to output the test clock signal Tclk when defect detection is performed by the conductive path TSV1 between T21 and T22, so as to prevent the test enable signals Test_en<1:n> from being erroneously shift-transmitted, which may result in inaccurate test results.

In the embodiments of the present disclosure, the clock shielding circuit 14 may shield the test clock signal Tclk when the test clock signal Tclk is not required to receive or transmit data, so as to ensure the accuracy of the test circuit 100 in performing the defect test, and effectively save the power consumption of the test circuit 100 as well.

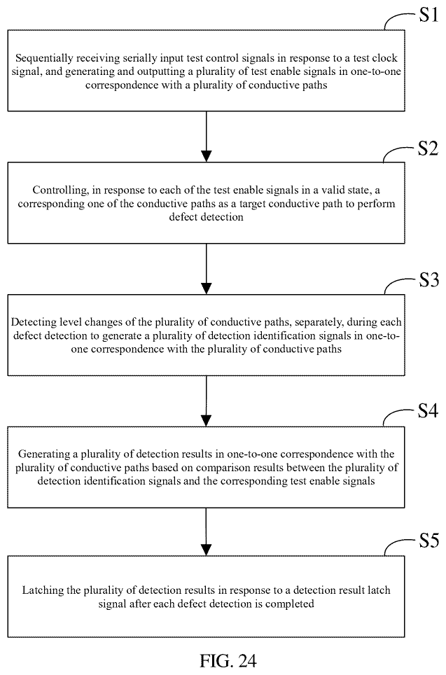

An embodiment of the present disclosure further provides a test method for the stacked chip structure 200. Referring to FIG. 24, the test method includes:
step S1: sequentially receiving serially input test control signals Test_in in response to a test clock signal Tclk, and generating and outputting a plurality of test enable signals Test_en<1:n> in one-to-one correspondence with a plurality of conductive paths 10;
step S2: controlling, in response to the test enable signal Test_en<i> in the valid state, a corresponding conductive path 10 as a target conductive path to perform defect detection;
step S3: detecting level changes of the plurality of conductive paths 10, separately, during each defect detection to generate a plurality of detection identification signals flag<1:n>in one-to-one correspondence with the plurality of conductive paths 10;
step S4: generating a plurality of detection results Result<1:n> in one-to-one correspondence with the plurality of conductive paths 10 based on comparison results Com<1:n>between the detection identification signals flag<1:n> and the corresponding test enable signals Test_en<1:n>; and
step S5: latching the detection results Result<1:n> in response to a detection result latch signal Update after each defect detection is completed.

With the above test method, defect detection of all conductive paths can be indicated only by test control signals serially input through one test port, such that test port resources can be effectively saved and test circuit complexity can be effectively reduced. In addition, level changes of all conductive paths are detected to generate detection results of the conductive paths while the defect test is only performed on a target conductive path each time, such that detection of all types of defects can be effectively covered, and the accuracy and comprehensiveness of defect detection of the conductive paths can be improved.

In some embodiments, the test method further includes:
step S6:serially outputting the latched detection results Result<1:n> as the test result signals Test_out in sequence based on the test clock signal Tclk after all the conductive paths 10 serve as the target conductive paths to complete defect detection or after each round of defect test is completed.

In some embodiments, step S6 specifically includes:
step S61: after all the conductive paths 10 serve as the target conductive paths to complete defect detection, reading all the latched detection results Result<1:n> in response to the test clock signal Tclk when a result readout identification signal Read_flag indicates a test result readout phase; and
step S62:serially outputting the read detection results Result<1:n> as the test result signals Test_out in sequence in response to the test clock signal Tclk when the result readout identification signal Read_flag indicates a data transmission phase.

In some embodiments, “latching the detection results Result<1:n> in response to a detection result latch signal Update” in step S5 specifically includes: keeping or updating, based on a current comparison result Com<1:n>between each detection identification signal flag<1:n> and a corresponding test enable signal Test_en<1:n>, each detection result Result<1:n> in response to the received detection result latch signal Update after any of the conductive paths 10 serves as the target conductive path to perform defect detection.

When the detection identification signal flag<i> is different from the corresponding test enable signal Test_en<i>, the corresponding detection result Result<i> is kept or updated to be a high level, and when the detection identification signal flag<i> is the same as the corresponding test enable signal Test_en<i>, the corresponding detection result Result<i> is kept unchanged; and the detection result Result<i>being the high level indicates that the corresponding conductive path 10 has a defect, and the detection result Result<i>being a low level indicates that the corresponding conductive path 10 has no defect.

In some embodiments, step S2 in the test method specifically includes:
S21: controlling, in response to the test enable signal Test_en<i> in the valid state, the first end of the target conductive path to be electrically connected to a power supply voltage VDD to perform a charging operation; and
S22: controlling the second end of the target conductive path and the second end of a conductive path adjacent to the target conductive path to be electrically connected to a grounding voltage GND, separately, to perform a discharging operation after the charging operation is completed.

In some embodiments, the plurality of conductive paths 10 are divided into a plurality of conductive path groups 110 arranged in arrays, each conductive path group 110 includes 1×m conductive paths 10 arranged in an array, and I and m are both positive integers greater than or equal to 2. In this case, step S2 in the test method specifically includes:
S23: using one conductive path 10 in each conductive path group 110 as the target conductive path in response to the plurality of test enable signals Test_en<i>, and controlling the first end of each target conductive path to be electrically connected to the power supply voltage VDD to perform the charging operation; and
S24: controlling the second end of a selected conductive path 10 to be electrically connected to the grounding voltage GND in response to a test region selection signal TSVSEL to perform a discharging operation.

The test region selection signal TSVSEL includes a plurality of test region selection sub-signals Tsvsel<1: p> in one-to-one correspondence with a plurality of position regions, each test region selection sub-signal Tsvsel<j>indicates whether conductive paths 10 in the corresponding position region are selected; and each position region includes at least one conductive path group 110.

It should be noted that the test methods provided in the above embodiments can be applied to the test circuit 100 in the foregoing embodiments, and for details not disclosed in the embodiments of the test methods, reference can be made to the descriptions of the foregoing embodiments of the test circuit 100, which are not repeated herein.

It should be noted that the terms “includes”, “including”, “comprises”, “comprising”, or any other variants are intended to cover non-exclusive inclusion herein. Thus, a process, method, item, or apparatus including a series of elements includes not only those elements but also other elements not explicitly listed, or elements inherent to such process, method, item, or apparatus. Without further limitation, an element defined by the phrase “including a . . . ” does not exclude the presence of additional identical elements in the process, method, item, or apparatus that includes the element.

The serial numbers of the embodiments of the present disclosure described above are for the purpose of describing only and do not represent the superiority or inferiority of the embodiments. The methods disclosed in the method embodiments provided in the present disclosure may be combined in any manner without conflict to obtain new method embodiments. The features disclosed in the product embodiments provided in the present disclosure may be combined in any manner without conflict to obtain new product embodiments. The features disclosed in the method or device embodiments provided in the present disclosure may be combined in any manner without conflict to obtain new method or device embodiments.

The above description shows only specific embodiments of the present disclosure, but the protection scope of the present disclosure is not limited thereto; changes or substitutions that any one skilled in the art can easily think of within the technical scope disclosed by the present disclosure shall fall within the protection scope of the present disclosure. Therefore, the protection scope of the present disclosure shall be subject to the protection scope of the claims.

What is claimed is:

1. A test circuit, comprising:
a plurality of conductive paths;
a test control circuit configured to sequentially receive serially input test control signals in response to a test clock signal, and generate and output a plurality of test enable signals in one-to-one correspondence with the plurality of conductive paths, wherein each of the plurality of test enable signals indicates whether a corresponding one of the plurality of conductive paths performs defect detection as a target conductive path in each defect detection;
a power control circuit electrically connected to each of the plurality of conductive paths and the test control circuit, separately, and configured to control, when the test enable signal is in a valid state, a corresponding conductive path as the target conductive path to sequentially perform charging and discharging operations; and
a defect detection circuit electrically connected to a first end of each of the plurality of conductive paths and the test control circuit, separately, and configured to detect level changes of the plurality of conductive paths separately to generate a plurality of detection identification signals in one-to-one correspondence with the plurality of conductive paths, and generate and output a plurality of detection results in one-to-one correspondence with the plurality of conductive paths based on one-to-one comparison results between the plurality of detection identification signals and the plurality of test enable signals.

2. The test circuit according to claim 1, wherein the test control circuit is further configured to regenerate and output a plurality of test enable signals after shift-transmitting the test control signals based on the test clock signal after each defect detection is completed;
wherein the test control circuit is further configured to serially output the plurality of detection results output by the defect detection circuit as test result signals in sequence based on the test clock signal after all the plurality of conductive paths serve as target conductive paths to complete defect detection.

3. The test circuit according to claim 1, wherein the test control circuit is further configured to receive a result readout identification signal, read all the plurality of detection results output by the defect detection circuit based on the test clock signal when the result readout identification signal indicates that the test control circuit is in a test result readout phase, and serially output the read plurality of detection results as the test result signals in sequence based on the test clock signal when the result readout identification signal indicates that the test control circuit is in a data transmission phase;
wherein the test control circuit is further configured to reset the plurality of test enable signals in response to a first reset signal after all the plurality of detection results are output.

4. The test circuit according to claim 1, wherein the test control circuit comprises a plurality of test control sub-circuits cascaded, the plurality of test control sub-circuits being in one-to-one correspondence with the plurality of conductive paths; and
a first input end of a test control sub-circuit of a first stage receives the test control signals, an output end of a test control sub-circuit of each stage is electrically connected to a first input end of a control sub-circuit of a next stage, a second input end of the test control sub-circuit of each stage receives a corresponding one of the plurality of detection results, a clock end of the test control sub-circuit of each stage receives the test clock signal, a control end of the test control sub-circuit of each stage receives the result readout identification signal, a reset end of the test control sub-circuit of each stage receives the first reset signal, an output end of the test control sub-circuit of each stage outputs a corresponding one of the plurality of test enable signals or a corresponding one of the plurality of detection results, and an output end of a test control sub-circuit of a last stage is further configured to serially output the plurality of detection results as the test result signals in sequence.

5. The test circuit according to claim 4, wherein each of the plurality of test control sub-circuits comprises:
a selector, wherein a first input end of the selector serves as the first input end of the test control sub-circuit, a second input end of the selector serves as the second input end of the test control sub-circuit to receive the corresponding one of the plurality of detection results, and a control end of the selector serves as the control end of the test control sub-circuit to receive the readout identification signal; and
a first D flip-flop, wherein an input end of the first D flip-flop is electrically connected to an output end of the selector, a clock end of the first D flip-flop serves as the control end of the test control sub-circuit to receive the test clock signal, an output end of the first D flip-flop serves as the output end of the test control sub-circuit to output the plurality of test enable signals, and a reset end of the first D flip-flop receives the first reset signal.

6. The test circuit according to claim 1, wherein the defect detection circuit is further configured to receive a detection result latch signal and latch each of the plurality of detection results in response to the detection result latch signal after each defect detection is completed;
wherein the defect detection circuit is further configured to latch, based on a current comparison result between each detection identification signal and a corresponding test enable signal, each of the plurality of detection results kept or updated in response to the received detection result latch signal after any of the plurality of conductive paths sequentially performs the charging and discharging operations as the target conductive path,
wherein when the detection identification signal is different from the corresponding test enable signal, the corresponding detection result is kept or updated to be a first level, and when the detection identification signal is the same as the corresponding test enable signal, the corresponding detection result is kept unchanged; and the detection result being the first level indicates that the corresponding conductive path has a defect, and the detection result being a second level indicates that the corresponding conductive path has no defect, wherein the first level is opposite to the second level.

7. The test circuit according to claim 6, wherein the defect detection circuit comprises a plurality of defect detection sub-circuits, the plurality of defect detection sub-circuits being in one-to-one correspondence with the plurality of conductive paths; and
each of the plurality of defect detection sub-circuits comprises:
a test signal detection sub-circuit electrically connected to a first end of a corresponding one of the plurality of conductive paths and configured to detect a level change of the conductive path to generate and output the detection identification signal; and
a test result latch sub-circuit electrically connected to the test signal detection sub-circuit and the test control circuit and configured to generate the detection result based on the comparison result between the detection identification signal and the corresponding test enable signal, and latch the detection result in response to the detection result latch signal.

8. The test circuit according to claim 7, wherein
the test signal detection sub-circuit comprises:
a first NOT gate, wherein an input end of the first NOT gate is electrically connected to a first end of a corresponding conductive path;
a second NOT gate, wherein an input end of the second NOT gate is electrically connected to an output end of the first NOT gate, and an output end of the second NOT gate is electrically connected to the input end of the first NOT gate; and
a second D flip-flop, wherein an input end of the second D flip-flop is electrically connected to a power supply voltage, a clock end of the second D flip-flop is electrically connected to the output end of the first NOT gate, and an output end of the second D flip-flop outputs the detection identification signal; and
the test result latch sub-circuit comprises:
a first exclusive-OR gate, wherein a first input end of the first exclusive-OR gate is electrically connected to the output end of the second D flip-flop, and a second input end of the first exclusive-OR gate receives a corresponding test enable signal;
a first OR gate, wherein a first input end of the first OR gate is electrically connected to an output end of the first exclusive-OR gate; and
a latch, wherein an input end of the latch is electrically connected to an output end of the first OR gate, a control end of the latch receives the detection result latch signal, an output end of the latch outputs the detection result, and the output end of the latch is further electrically connected to a second input end of the first OR gate.

9. The test circuit according to claim 8, wherein
a reset end of the second D flip-flop receives a second reset signal, and the second D flip-flop resets the detection identification signal in response to the second reset signal after each latching of the detection result; and
a reset end of the latch receives a third reset signal, and the latch resets the detection result in response to the third reset signal after all the detection results are output.

10. The test circuit according to claim 1, wherein
the power control circuit comprises:
a first power control circuit electrically connected to the first end of each of the plurality of conductive paths and the test control circuit, separately, and configured to control a first end of the target conductive path to be electrically connected to the power supply voltage or a grounding voltage when the test enable signal is in the valid state; and
a second power control circuit electrically connected to a second end of each of the plurality of conductive paths, separately, and configured to control the second end of the conductive path to be electrically connected to the grounding voltage or the power supply voltage.

11. The test circuit according to claim 10, wherein
the plurality of conductive paths are divided into a plurality of conductive path groups arranged in arrays, each of the plurality of conductive path groups comprises 1×m conductive paths arranged in an array, and I and m are both positive integers greater than or equal to 2;
wherein the first power control circuit is further configured to use one conductive path in each of the plurality of conductive path groups as the target conductive path based on the plurality of test enable signals in each defect detection, and control the first end of each of the target conductive paths to be electrically connected to the power supply voltage or the grounding voltage;
wherein the second power control circuit is further configured to receive a test region selection signal, and control a second end of a selected conductive path to be electrically connected to the grounding voltage or the power supply voltage based on the test region selection signal,
wherein the test region selection signal comprises a plurality of test region selection sub-signals in one-to-one correspondence with a plurality of position regions, each of the plurality of test region selection sub-signals indicates whether conductive paths in a corresponding one of the plurality of position regions are selected; and each of the plurality of position regions comprises at least one conductive path group.

12. The test circuit according to claim 11, wherein
the first power control circuit comprises a plurality of first power supply control sub-circuits, the second power control circuit comprises a plurality of second power supply control sub-circuits, and the plurality of first power supply control sub-circuits and the plurality of second power supply control sub-circuits are in one-to-one correspondence with the plurality of conductive paths, separately.

13. The test circuit according to claim 12, wherein
each of the plurality of first power supply control sub-circuits comprises:
a first AND gate, wherein a first input end of the first AND gate receives a pull-down control signal, and a second input end of the first AND gate receives a corresponding test enable signal; and
a first N-type transistor, wherein a first end of the first N-type transistor is electrically connected to the first end of the conductive path, a second end of the first N-type transistor is electrically connected to the grounding voltage, and a control end of the first N-type transistor is electrically connected to an output end of the first AND gate; and
each of the plurality of second power supply control sub-circuits comprises:
a second AND gate, wherein a first input end of the second AND gate receives a pull-up control signal, and a second input end of the second AND gate receives a corresponding one of the plurality of test region selection sub-signals; and
a first P-type transistor, wherein a first end of the first P-type transistor is electrically connected to the second end of the conductive path, a second end of the first P-type transistor is electrically connected to the power supply voltage, and a control end of the first P-type transistor is electrically connected to an output end of the second AND gate; or
wherein each of the plurality of first power supply control sub-circuits comprises:
a third AND gate, wherein a first input end of the third AND gate receives a pull-up control signal, and a second input end of the third AND gate receives a corresponding test enable signal; and
a second P-type transistor, wherein a first end of the second P-type transistor is electrically connected to the first end of the conductive path, a second end of the second P-type transistor is electrically connected to the power supply voltage, and a control end of the second P-type transistor is electrically connected to an output end of the third AND gate; and
each of the plurality of second power supply control sub-circuits comprises:
a fourth AND gate, wherein a first input end of the fourth AND gate receives a pull-down control signal, and a second input end of the fourth AND gate receives a corresponding one of the plurality of test region selection sub-signals; and
a second N-type transistor, wherein a first end of the second N-type transistor is electrically connected to the second end of the conductive path, a second end of the second N-type transistor is electrically connected to the grounding voltage, and a control end of the second N-type transistor is electrically connected to an output end of the fourth AND gate.

14. The test circuit according to claim 9, wherein the further comprises a plurality of holding circuits, the plurality of holding circuits power control circuit being in one-to-one correspondence with the plurality of conductive paths; and
each of the plurality of holding circuits comprises:
a third NOT gate, wherein an input end of the third NOT gate is electrically connected to a second end of a corresponding one of the plurality of conductive paths; and
a fourth NOT gate, wherein an input end of the fourth NOT gate is electrically connected to an output end of the third NOT gate, and an output end of the fourth NOT gate is electrically connected to the input end of the third NOT gate.

15. The test circuit according to claim 9, wherein the test circuit is applied in a stacked chip structure, and the stacked chip structure comprises: a first chip and a second chip stacked on the first chip; and
the first power control circuit, the test control circuit, and the defect detection circuit are all arranged in the first chip, the second power control circuit is arranged in the second chip, and the plurality of conductive paths are used for transmitting signals between the first chip and the second chip.

16. The test circuit according to claim 1, wherein the test circuit further comprises:
a clock shielding circuit connected to the test control circuit and configured to receive an initial clock signal, generate and output the test clock signal based on the initial clock signal when none of the plurality of conductive paths performs defect detection, and output no test clock signal when any of the plurality of conductive paths performs defect detection.

17. A test method for a stacked chip structure, comprising:
sequentially receiving serially input test control signals in response to a test clock signal, and generating and outputting a plurality of test enable signals in one-to-one correspondence with a plurality of conductive paths;
controlling, in response to each of the plurality of test enable signals in a valid state, a corresponding one of the plurality of conductive paths as a target conductive path to perform defect detection;
detecting level changes of the plurality of conductive paths, separately, during each defect detection to generate a plurality of detection identification signals in one-to-one correspondence with the plurality of conductive paths;
generating a plurality of detection results in one-to-one correspondence with the plurality of conductive paths based on comparison results between the plurality of detection identification signals and the corresponding plurality of test enable signals; and
latching the plurality of detection results in response to a detection result latch signal after each defect detection is completed.

18. The test method according to claim 17, further comprising:
serially outputting the plurality of detection results latched by a defect detection circuit as test result signals in sequence based on the test clock signal after all the plurality of conductive paths serve as the target conductive paths to complete defect detection or after each round of defect test is completed;
wherein serially outputting the plurality of detection results latched as the test result signals in sequence based on the test clock signal after all the plurality of conductive paths serve as the target conductive paths to complete defect detection or after each round of defect test is completed comprises:
after all the plurality of conductive paths serve as the target conductive paths to complete defect detection, reading all the latched plurality of detection results in response to the test clock signal when a result readout identification signal indicates a test result readout phase, and serially outputting the read plurality of detection results as the test result signals in sequence in response to the test clock signal when the result readout identification signal indicates a data transmission phase.

19. The test method according to claim 17, wherein
latching the plurality of detection results in response to the detection result latch signal comprises:
keeping or updating, based on a current comparison result between each detection identification signal and a corresponding test enable signal, each of the plurality of detection results in response to the received detection result latch signal after any of the plurality of conductive paths serves as the target conductive path to perform defect detection,
wherein when the detection identification signal is different from the corresponding test enable signal, the corresponding detection result is kept or updated to be a high level, and when the detection identification signal is the same as the corresponding test enable signal, the corresponding detection result is kept unchanged; and the detection result being the high level indicates that the corresponding conductive path has a defect, and the detection result being a low level indicates that the corresponding conductive path has no defect;
wherein controlling, in response to each of the plurality of test enable signals in the valid state, the corresponding one of the plurality of conductive paths as the target conductive path to sequentially perform defect detection comprises:
controlling, in response to the test enable signal in the valid state, a first end of the target conductive path to be electrically connected to a power supply voltage to perform a charging operation; and
controlling a second end of the target conductive path and a second end of a conductive path adjacent to the target conductive path to be electrically connected to a grounding voltage, separately, to perform a discharging operation after the charging operation is completed.

20. The test method according to claim 17, wherein the plurality of conductive paths are divided into a plurality of conductive path groups arranged in arrays, each of the plurality of conductive path groups comprises 1×m conductive paths arranged in an array, and 1 and m are both positive integers greater than or equal to 2; and
controlling, in response to each of the plurality of test enable signals in the valid state, the corresponding one of the plurality of conductive paths as the target conductive path to perform defect detection comprises:
using one conductive path in each of the plurality of conductive path groups as the target conductive path in response to the plurality of test enable signals, and controlling the first end of each of the target conductive paths to be electrically connected to the power supply voltage to perform the charging operation; and
controlling a second end of a selected conductive path to be electrically connected to the grounding voltage in response to a test region selection signal to perform the discharging operation,
wherein the test region selection signal comprises a plurality of test region selection sub-signals in one-to-one correspondence with a plurality of position regions, each of the plurality of test region selection sub-signals indicates whether conductive paths in a corresponding one of the plurality of position regions are selected; and each of the plurality of position regions comprises at least one conductive path group.
